(19) United States
(12) Patent Application Publication
(10) Pub. No.: US 2025/0351529 A1
(43) Pub. Date: Nov. 13, 2025

(54) SEMICONDUCTOR STRUCTURE AND METHOD FOR MANUFACTURING THE SAME

(71) Applicant: Taiwan Semiconductor Manufacturing Company, Ltd., Hsinchu (TW)

(72) Inventors: Hsien-Chih HUANG, Hsinchu City (TW); Guan-Lin CHEN, Baoshan City (TW); Kuo-Cheng CHIANG, Zhubei Township (TW); Chih-Hao WANG, Baoshan Township (TW); Shi-Ning JU, Hsinchu City (TW)

(73) Assignee: Taiwan Semiconductor Manufacturing Company, Ltd., Hsinchu (TW)

(21) Appl. No.: 18/659,873

(22) Filed: May 9, 2024

(51) Int. Cl. H01L 29/49; G11C 11/412; H01L 21/28; H01L 29/06; H01L 29/423; H01L 29/66; H01L 29/775; H03K 19/21

(52) U.S. Cl. CPC H10D 64/679; H01L 21/28123; H10D 30/014; H10D 30/43; H10D 30/6735; H10D 62/121; H10D 64/017; H10D 64/018; G11C 11/412; H03K 19/21

(57) ABSTRACT

A method for manufacturing a semiconductor structure includes forming a fin over a substrate. The fin includes first semiconductor layers and second semiconductor layers alternating stacked in a first direction. The method also includes forming a dummy gate structure over the fin, forming first gate spacers on opposite sides of the dummy gate structure in a second direction, forming source/drain features on opposite sides of the dummy gate structure in the second direction, replacing the dummy gate structure and the first semiconductor layers with a gate structure, replacing the first gate spacers with second gate spacers, and forming inner spacers between the second semiconductor layers in the first direction. The gate structure wraps around the first semiconductor layers. Each of the second gate spacers has a first air gap. Each of the inner gate spacers has a second air gap.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs and, for these advancements to be realized, similar developments in IC processing and manufacturing are needed.

As integrated circuit (IC) technologies progress towards smaller technology nodes, gate-all-around (GAA) devices have been incorporated into memory devices (including, for example, static random-access memory, or SRAM, cells) and core devices (including, for example, standard logic, or STD, cells) to reduce chip footprint while maintaining reasonable processing margins.

However, as GAA devices continue to be scaled down, conventional methods for manufacturing GAA devices may experience challenges. Accordingly, although existing technologies for fabricating GAA devices have been generally adequate for their intended purposes, they have not been entirely satisfactory in all aspects.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a fragmentary diagrammatic top view of an integrated circuit (IC) chip, in portion or entirety, in accordance with some embodiments of the present disclosure.

FIGS. 2A, 2B, and 2C illustrate circuit schematics of various STD cells that can be implemented in the logic region of the IC chip of FIG. 1 in accordance with some embodiments of the present disclosure.

FIGS. 3 and 4 illustrate circuit schematics of a static random access memory (SRAM) cell that can be implemented in the memory region of the IC chip of FIG. 1, in accordance with some embodiments of the present disclosure.

FIGS. 5, 6, and 7 are perspective views of a workpiece at various fabrication stages, in accordance with some embodiments of the present disclosure.

FIGS. 8, 9, 10, 11, 12, 13, 14, and 15 are X-Z cross-sectional views of the workpiece at various fabrication stages along a line A-A′ of FIG. 7, in accordance with some embodiments of the present disclosure.

FIGS. 16A, 17A, 18A, 19A, and 20A are perspective views of the workpiece at various fabrication stages, in accordance with some embodiments of the present disclosure.

FIGS. 16B, 17B, 18B, 19B, and 20B are X-Z cross-sectional views of the workpiece at various fabrication stages along lines A-A′ of FIGS. 16A, 17A, 18A, 19A, and 20A, respectively, in accordance with some embodiments of the present disclosure.

FIGS. 16C, 17C, and 18C are Y-Z cross-sectional views of the workpiece at various fabrication stages along lines B-B′ of FIGS. 16A, 17A, and 18A, respectively, in accordance with some embodiments of the present disclosure.

FIGS. 21A and 22A are perspective views of the workpiece at various fabrication stages, in accordance with some alternative embodiments of the present disclosure.

FIGS. 21B and 22B are X-Z cross-sectional views of the workpiece at various fabrication stages along lines A-A′ of FIGS. 21A and 22A, respectively, in accordance with some alternative embodiments of the present disclosure.

FIGS. 23, 24, 25, 26, 27A, 28A, and 29A are X-Z cross-sectional views of the workpiece at various fabrication stages, in accordance with some alternative embodiments of the present disclosure.

FIGS. 27B, 28B, and 29B are Y-Z cross-sectional views of the workpiece at various fabrication stages along lines C-C′ of FIGS. 27A, 28A, and 29A, respectively, in accordance with some alternative embodiments of the present disclosure.

FIGS. 30 and 31 are X-Z cross-sectional views of the workpiece at various fabrication stages, in accordance with some alternative embodiments of the present disclosure.

FIG. 32A is a partial enlarged cross-sectional view of the workpiece at the fabrication stage in a dashed box of FIG. 20B, in accordance with some alternative embodiments of the present disclosure.

FIGS. 32B and 32C are partial enlarged cross-sectional views of the workpiece at the fabrication stage in the dashed box of FIG. 20B, in accordance with some alternative embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure is generally related to semiconductor structures, and more particularly to semiconductor structures with field-effect transistors (FETs), such as three-dimensional gate-all-around (GAA) transistors, in memory (e.g., SRAM) and/or standard logic cells of an integrated circuit (IC) structure. Generally, a GAA transistor may include a plurality of vertically stacked sheets (e.g., nanosheets), wires (e.g., nanowires), or rods (e.g., nanorods) in a channel region of the transistor, thereby allowing better gate control, lowered leakage current, and improved scaling capability for various IC applications. While existing technologies for fabricating GAA transistors have been generally adequate for their intended applications, they have not been entirely satisfactory in all aspects.

The gate-all-around (GAA) transistor structures may be patterned by any suitable method. For example, the structures may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the GAA structure.

Embodiments of the present disclosure offer advantages over the existing art, though it is understood that other embodiments may offer different advantages, not all advantages are necessarily discussed herein, and no particular advantage is required for all embodiments. For example, embodiments discussed herein include methods and structures including gate spacers and inner spacers with air gaps, such that the parasitic capacitance of the GAA transistor, thereby improving the performance of the GAA transistor. The details of the structure and manufacturing methods of the present disclosure are described below in conjunction with the accompanying drawings, which illustrate the process of making GAA transistor structures, according to some embodiments.

The various aspects of the present disclosure will now be described in more detail with reference to the figures. For avoidance of doubts, an X-direction, a Y-direction, and a Z-direction in the figures are perpendicular to one another and are used consistently. Throughout the present disclosure, like reference numerals denote like features unless otherwise indicated. The X-direction, the Y-direction, and the Z-direction can be arbitrarily referred to as the first direction, the second direction, or the third direction in the order of appearance. For example, the Z-direction can be referred to as the first direction, and one of the X-direction and the Y-direction can be referred to as the second direction, and the other one of the X-direction and the Y-direction can be referred to as the third direction.

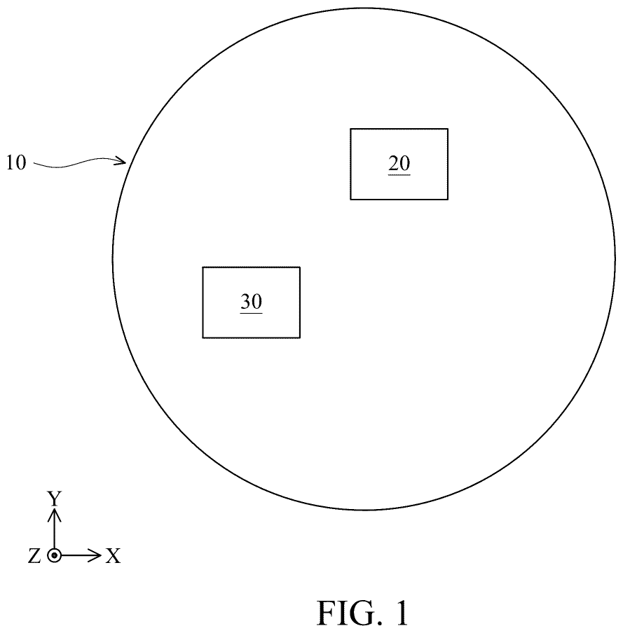

FIG. 1 is a fragmentary diagrammatic top view of an integrated circuit (IC) chip 10, in portion or entirety, in accordance with some embodiments of the present disclosure. The IC chip 10 may include various passive microelectronic devices and active microelectronic devices, such as resistors, capacitors, inductors, diodes, P-type field effect transistors (PFETs), n-type field effect transistors (NFETs), metal-oxide semiconductor field effect transistors (MOSFETs), CMOS transistors, bipolar junction transistors (BJTs), laterally diffused MOS (LDMOS) transistors, high voltage transistors, high frequency transistors, other suitable components, or a combination thereof.

The various microelectronic devices can be configured to provide the IC chip 10 with functionally distinct regions, such as a core region (also referred to as a logic region), a memory region (e.g., a static random access memory (SRAM) region), an analog region, a peripheral region (also referred to as an input/output (I/O) region), a dummy region, and/or other suitable region. In some embodiments, the IC chip 10 includes a memory region 20 and a logic region 30.

The memory region 20 can include an array of memory cells, each of which includes transistors and interconnection structures (also referred to as routing structures) that combine to provide a storage device and/or a storage function, such as a flip flop, a latch, other suitable memory devices, or combinations thereof. In some embodiments, the memory region 20 is configured with static random-access memory (SRAM) cells, dynamic random-access memory (DRAM) cells, non-volatile random-access memory (NVRAM) cells, flash memory cells, other suitable memory cells, or combinations thereof.

The logic region 30 can include an array of circuit cells having various logic cells or standard (STD) cells. The logic cells or STD cells may include transistors and interconnection structures that combine to provide a logic device and/or a logic function, such as an inverter, an AND, an NAND, an OR, an NOR, a NOT, an XOR, an XNOR, other suitable logic devices, or combinations thereof. FIG. 1 has been simplified for the sake of clarity to better understand the inventive concepts of the present disclosure. Additional features can be added in IC chip 10, and some of the features described herein can be replaced, modified, or eliminated in other embodiments of the IC chip 10.

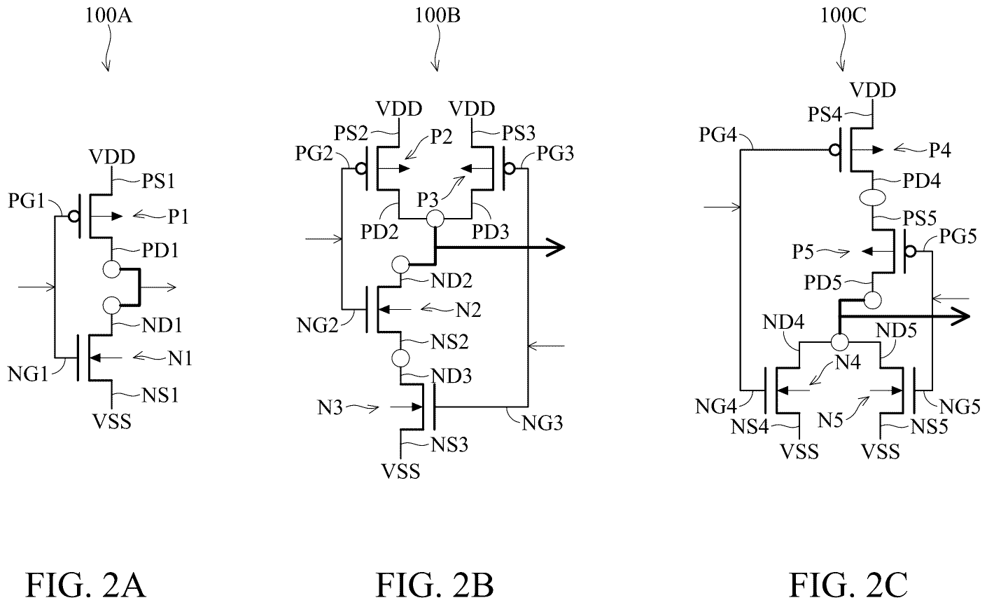

FIGS. 2A to 2E are circuit schematics of various STD cells in the array of circuit cells in the logic region 30 of the IC chip 10, in accordance with some embodiments of the present disclosure.

FIG. 2A shows an inverter 100A including an N-type transistor N1 and a P-type transistor P1. The N-type transistor N1 includes a source terminal NS1, a drain terminal ND1, and a gate terminal NG1, and the P-type transistor P1 includes a source terminal PS1, a drain terminal PD1, and a gate terminal PG1.

As shown in FIG. 2A, the gate terminals NG1 and PG1 are coupled with each other to operate as an input terminal of the inverter 100A. The drain terminals ND1 and PD1 are coupled with each other to operate as an output terminal of the inverter 100A. The source terminal PS1 is coupled to a VDD voltage. The source terminal NS1 is coupled to a VSS voltage (or a ground voltage).

FIG. 2B shows a NAND (also referred to as a NAND logic gate, a NAND device or a NAND cell) 100B including N-type transistors N2, N3 and P-type transistors P2, P3. The N-type transistor N2 includes a source terminal NS2, a drain terminal ND2, and a gate terminal NG2, and the N-type transistor N3 includes a source terminal NS3, a drain terminal ND3, and a gate terminal NG3. The P-type transistor P2 includes a source terminal PS2, a drain terminal PD2, and a gate terminal PG2, and the P-type transistor P3 includes a source terminal PS3, a drain terminal PD3, and a gate terminal PG3.

As shown in FIG. 2B, the gate terminals NG2 and PG2 are coupled with each other to operate as a first input terminal of the NAND 100B, and the gate terminals NG3 and PG3 are coupled with each other to operate as a second input terminal of the NAND 100B. The drain terminals ND2, PD2, and PD3 are coupled with each other to operate as an output terminal of the NAND 100B. In some embodiments, the connection of the drain terminals ND2, PD2, and PD3 are referred to as a “common drain.” The source terminals PS2 and PS3 are coupled to the VDD voltage. The source terminal NS3 is coupled to VSS voltage (or a ground voltage). The source terminal NS2 and drain terminal ND3 are coupled with each other.

FIG. 2C shows a NOR (also referred to as a NOR logic gate, a NOR device or a NOR cell) 100C including N-type transistors N4, N5 and P-type transistors P4, P5. The N-type transistor N4 includes a source terminal NS4, a drain terminal ND4, and a gate terminal NG4, and the N-type transistor N5 includes a source terminal NS5, a drain terminal ND5, and a gate terminal NG5. The P-type transistor P4 includes a source terminal PS4, a drain terminal PD4, and a gate terminal PG4, and the P-type transistor P5 includes a source terminal PS5, a drain terminal PD5, and a gate terminal PG5.

As shown in FIG. 2C, the gate terminals NG4 and PG4 are coupled with each other to operate as a first input terminal of the NOR 100C, and the gate terminals NG5 and PG5 are coupled with each other to operate as a second input terminal of the NOR 100C. The drain terminals ND4, ND5, and PD5 are coupled with each other to operate as an output terminal of the NOR 100C. In some embodiments, the connection of the drain terminals ND4, ND5, and PD5 are referred to as “common drain.” The source terminal PS4 is coupled to the VDD voltage. The source terminals NS4 and NS5 are coupled to VSS voltage (or a ground voltage). The source terminal PS5 and drain terminal PD4 are coupled with each other.

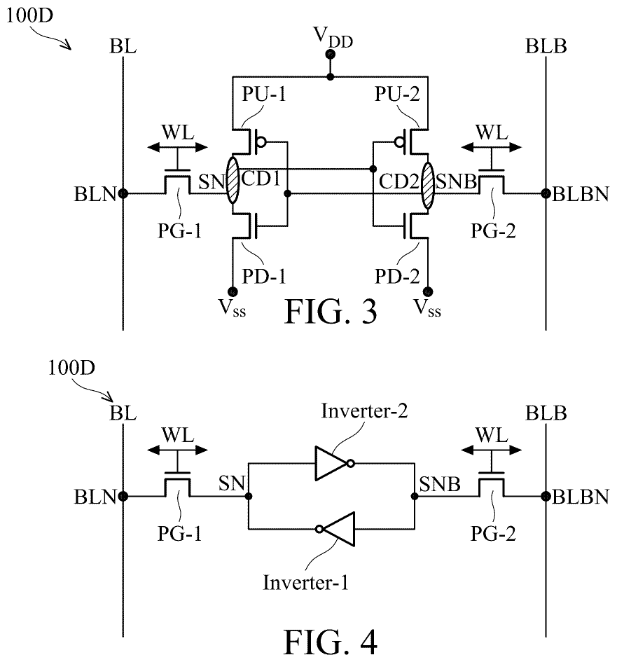

FIGS. 3 and 4 are circuit diagrams of an SRAM circuit that can be implemented in an SRAM cell of an array in the memory region 20 of FIG. 1, in accordance with some embodiments of the present disclosure. The circuit diagram of SRAM cell is merely exemplary, and in some embodiments, each of SRAM cells in the array is configured with an SRAM circuit similar to the SRAM cells 100D as shown in FIGS. 2 and 3. For example, each of SRAM cells has a storage portion that includes a cross-coupled pair of inverters (also referred to as a latch), such as an Inverter-1 and an Inverter-2. Inverter-1 includes pull-up transistor PU-1 and pull-down transistor PD-1, and Inverter-2 includes pull-up transistor PU-2 and pull-down transistor PD-2. Pass-gate transistor PG-1 is connected to an output of Inverter-1 and an input of Inverter-2, and pass-gate transistor PG-2 is connected to an output of Inverter-2 and an input of Inverter-1.

In operation, pass-gate transistor PG-1 and pass-gate transistor PG-2 provide access to the storage portion of their respective SRAM cell (i.e., Inverter-1 and Inverter-2) and can also be referred to as access transistors of their respective SRAM cell. Each of SRAM cells is connected to and powered through a first power supply voltage, such as a positive power supply voltage, and a second power supply voltage, such as a ground voltage or a reference voltage (which can be an electrical ground).

A gate of pull-up transistor PU-1 interposes a source, which is electrically coupled to the first power supply voltage via a voltage node (or voltage source) VDD, and a first common drain (CD1) (i.e., a drain of pull-up transistor PU-1 and a drain of pull-down transistor PD-1). A gate of pull-down transistor PD-1 interposes a source, which is electrically coupled to the second power supply voltage via a voltage node (or voltage source) V_{SS}, and the first common drain.

A gate of pull-up transistor PU-2 interposes a source, which is electrically coupled to the first power supply voltage via voltage node V_{DD}, and a second common drain (CD-2) (i.e., a drain of pull-up transistor PU-2 and a drain of pull-down transistor PD-2). A gate of pull-down transistor PD-2 interposes a source, which is electrically coupled to the second power supply voltage via voltage node V_{SS}, and the second common drain.

The first common drain provides a storage node SN that stores data in true form, and the second common drain provides a storage node SNB that stores data in complementary form, or vice versa, in some embodiments. The gate of pull-up transistor PUI and the gate of pull-down transistor PD-1 are coupled together and to the second common drain SD2, and the gate of pull-up transistor PU-2 and the gate of pull-down transistor PD-2 are coupled together and to the first common drain SD1.

A gate of pass-gate transistor PG-1 interposes a drain connected to a bit line node BLN, which is electrically coupled to a bit line BL, and a source, which is electrically coupled to the first common drain SD1. A gate of pass-gate transistor PG-2 interposes a drain connected to a complementary bit line node BLBN, which is electrically coupled to a complementary bit line BLB, and a source, which is electrically coupled to the second common drain SD2.

Gates of pass-gate transistors PG-1, PG-2 are connected to and controlled by a word line WL, which allows selection of a respective SRAM cell for reading and/or writing. In some embodiments, pass-gate transistors PG-1, PG-2 provide access to storage nodes SN, SNB, respectively, each of which can store a bit (e.g., a logical 0 or a logical 1), during read operations and/or write operations. For example, pass-gate transistors PG-1, PG-2 couple storage nodes SN, SNB, respectively, to bit line BL and bit line bar BLB in response to voltage applied to the gates of the pass-gate transistors PG-1, PG-2 by the word line WL. In some embodiments, SRAM cells are single-port SRAMs. In some embodiments, SRAM cells are configured as multi-port SRAMs, such as dual-port SRAMs, and/or with more or less transistors than depicted, such as 8T SRAMs.

FIGS. 3 and 4 have been simplified for the sake of clarity to better understand the inventive concepts of the present disclosure. Additional features can be added in the SRAM circuits of FIGS. 3 and 4, and some of the features described herein can be replaced, modified, or eliminated in other embodiments of the SRAM circuits of FIGS. 3 and 4.

Each of the circuit cells and the SRAM cells discussed above is constructed by transistors. The transistors may be planar transistors, fin field-effect transistor (FinFET) transistors, gate-all-around (GAA) transistors, nano-wire transistors, nano-sheet transistors, or a combination thereof. For the sake of providing an example, exemplary GAA transistors for the circuit cells and the SRAM cells discussed above are illustrated and described below. More specifically, the manufacturing method and the structure of GAA transistors with improved dielectric layer between nanostructures and substrate for the circuit cells and the SRAM cells discussed above are illustrated and described below. However, it should be understood that the application should not be limited to a particular type of device, except as specifically claimed.

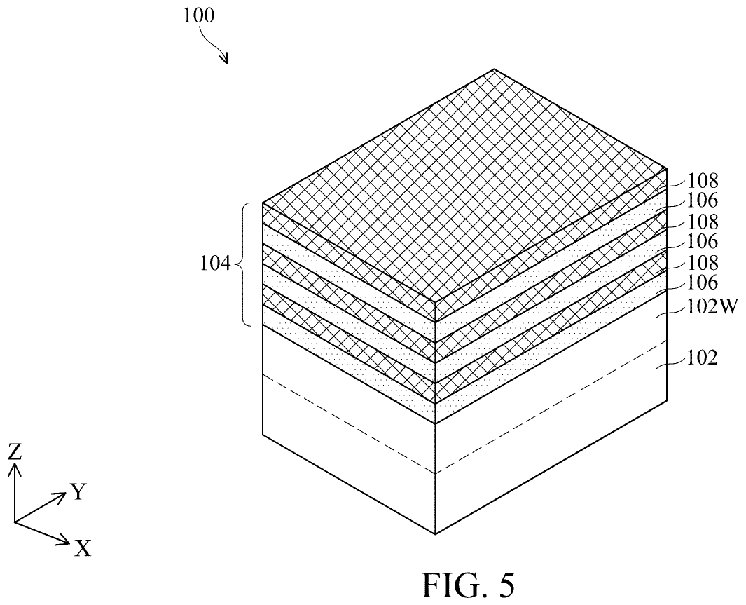

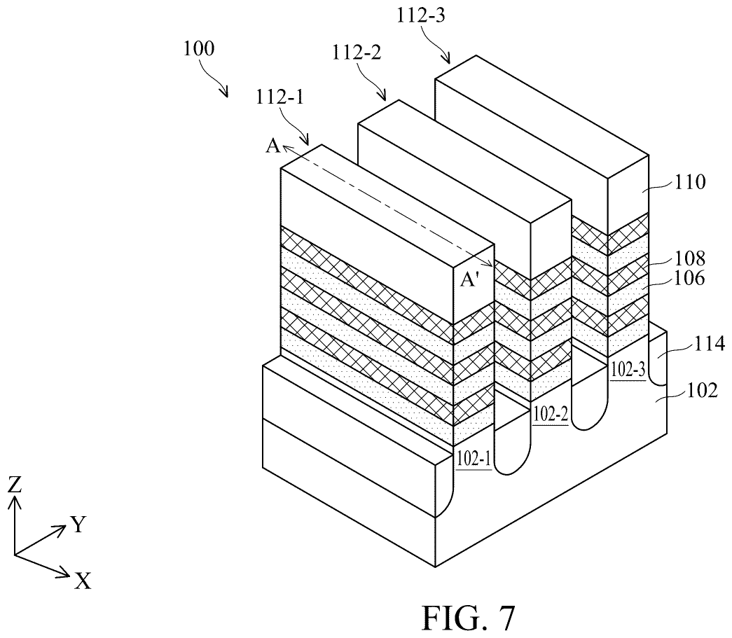

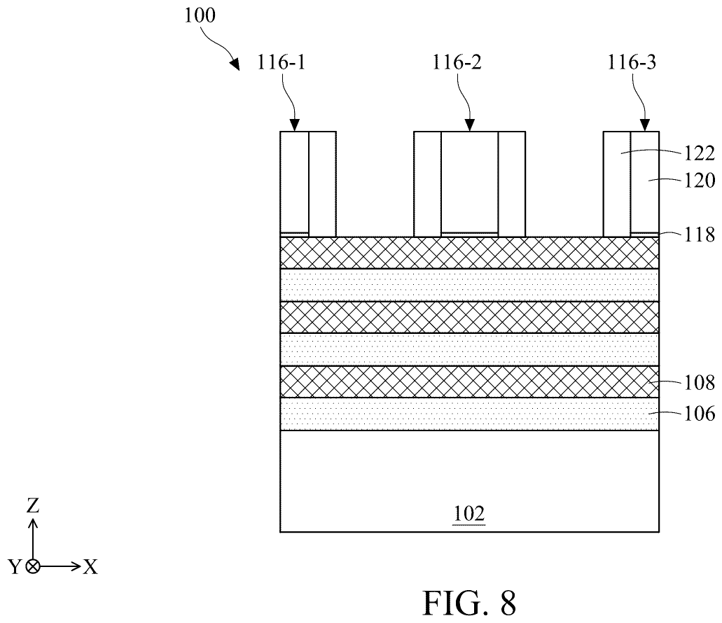

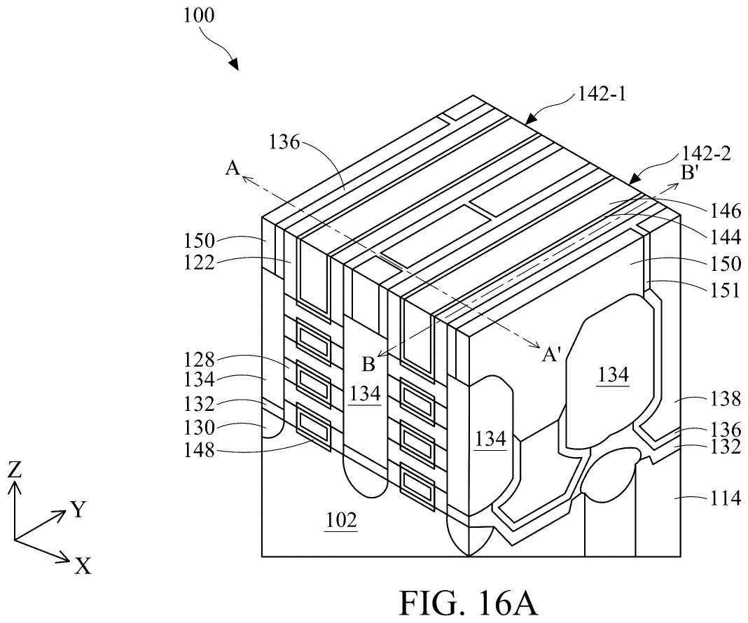

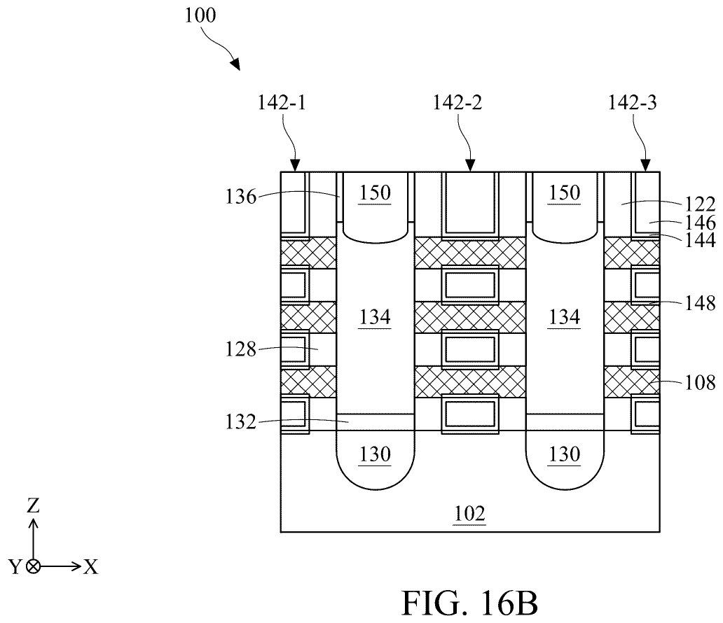

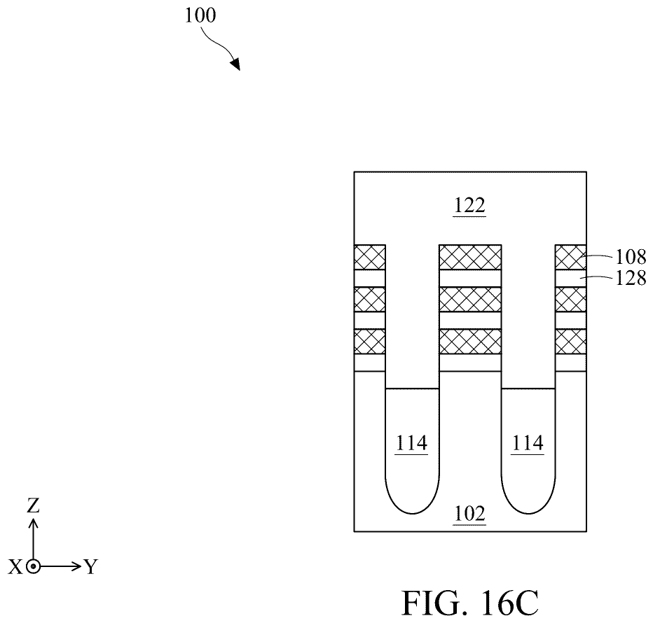

FIGS. 5, 6, and 7 are perspective views of a workpiece 100 at various fabrication stages, in accordance with some embodiments of the present disclosure. FIGS. 8, 9, 10, 11, 12, 13, 14, and 15 are X-Z cross-sectional views of the workpiece 100 at various fabrication stages along a line A-A′ of FIG. 7, in accordance with some embodiments of the present disclosure. FIGS. 16A, 17A, 18A, 19A, and 20A are perspective views of the workpiece 100 at various fabrication stages, in accordance with some embodiments of the present disclosure. FIGS. 16B, 17B, 18B, 19B, and 20B are X-Z cross-sectional views of the workpiece 100 at various fabrication stages along lines A-A′ of FIGS. 16A, 17A, 18A, 19A, and 20A, respectively, in accordance with some embodiments of the present disclosure. FIGS. 16C, 17C, and 18C are Y-Z cross-sectional views of the workpiece 100 at various fabrication stages along lines B-B′ of FIGS. 16A, 17A, and 18A, respectively, in accordance with some embodiments of the present disclosure.

Referring to FIG. 5, the workpiece 100 is provided. The workpiece 100 may include a substrate 102 and a stack 104 over the substrate 102. In some embodiments, the substrate 102 contains a semiconductor material, such as bulk silicon (Si). Alternatively or additionally, in some other embodiments, another elementary semiconductor, such as germanium (Ge) in a crystalline structure, may also be included in the substrate 102. The substrate 102 may also include a compound semiconductor, such as silicon germanium (SiGe) or a III-V semiconductor material. Example III-V semiconductor materials may include silicon carbide (SiC), indium arsenide (InAs), indium antimonide (InSb), indium phosphide (InP), gallium arsenide (GaAs), gallium phosphide (GaP), gallium nitride (GaN), gallium arsenide phosphide (GaAsP), aluminum indium arsenide (AlInAs), aluminum gallium arsenide (AlGaAs), gallium indium phosphide (GaInP), and/or indium gallium arsenide (InGaAs), or combinations thereof. The substrate 102 may also include an insulating layer, such as a silicon oxide layer, to have a semiconductor-on-insulator substrate, such as Si-on-insulator (SOI), SiGe-on-insulator (SGOI), Ge-on-insulator (GOI) substrates.

In some embodiments, the substrate 102 may include various doped regions configured according to design requirements of GAA transistors. In some embodiments, the substrate 102 may include a doped region 102W (also referred to as a well region). The doped region 102W may be an n-type doped region (also referred to as an n-well) or a p-type doped region (also referred to as a p-well), and the n-type doped region is configured for a p-type metal-oxide-semiconductor (PMOS) transistor and the p-type doped region is configured for an n-type MOS (NMOS) transistor. N-type doped region is doped with n-type dopants, such as phosphorus (P), arsenic (As), other n-type dopant, or combinations thereof. P-type doped region is doped with p-type dopants, such as boron (B), indium (In), other p-type dopant, or combinations thereof.

In the present embodiment, the substrate 102 shows one doped region 102W. In other embodiments, substrate 102 may include multiple doped regions formed with a combination of p-type dopants and n-type dopants. An ion implantation process, a diffusion process, and/or other suitable doping process can be performed to form the various doped regions. In some embodiments, n-type doped region has an n-type dopant concentration of about 5×10¹⁶ cm⁻³ to about 5×10¹⁹ cm⁻³, and p-type doped region has a p-type dopant concentration of about 5×10¹⁶ cm⁻³ to about 5×10¹⁹ cm⁻³. Because the workpiece 100 will be fabricated into a semiconductor structure 100 upon conclusion of the fabrication processes, the workpiece 100 may be referred to as the semiconductor structure 100 as the context requires.

The stack 104 includes semiconductor layers 106 and 108, and the semiconductor layers 106 and 108 are alternatingly stacked in the Z-direction. The semiconductor layers 106 and the semiconductor layers 108 may have different semiconductor compositions. In some embodiments, semiconductor layers 106 are formed of silicon germanium (SiGe) and the semiconductor layers 108 are formed of silicon (Si). In these embodiments, the additional germanium content in the semiconductor layers 106 allow selective removal or recess of the semiconductor layers 106 without substantial damages to the semiconductor layers 108, so that the semiconductor layers 106 are also referred to as sacrificial layers.

In some embodiments, the semiconductor layers 106 and 108 are epitaxially grown over (on) the substrate 102 using a deposition technique such as epitaxial growth, vapor-phase epitaxy (VPE), molecular beam epitaxy (MBE), although other deposition processes, such as chemical vapor deposition (CVD), low pressure CVD (LPCVD), atomic layer deposition (ALD), ultrahigh vacuum CVD (UHVCVD), reduced pressure CVD (RPCVD), a combination thereof, or the like, may also be utilized. The semiconductor layers 106 and the semiconductor layers 108 are deposited alternatingly, one-after-another, to form the stack 104.

It should be noted that three (3) layers of the semiconductor layers 106 and three (3) layers of the semiconductor layers 108 are alternately and vertically arranged (or stacked) as shown in FIG. 5, which are for illustrative purposes only and not intended to be limiting beyond what is specifically recited in the claims. The number of layers depends on the desired number of channel members for the semiconductor device. In some embodiments, there may be from 2 to 10 semiconductor layers 106 alternating with 2 to 10 semiconductor layers 108 in the stack 104.

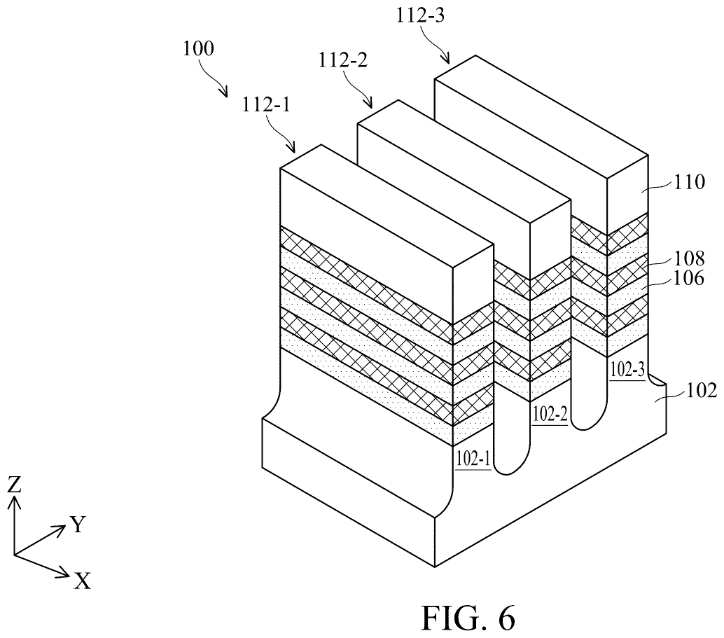

Referring to FIG. 6, the substrate 102 and the stack 104 are then patterned to form a fins 112-1 to 112-3 (may be collectively referred to as fins 112) over the substrate 102. For patterning purposes, the workpiece 100 may also include a hard mask layer 110 over the stack 104 before the patterning of the substrate 102 and the stack 104. The hard mask layer 110 may be a single layer or a multi-layer. In some embodiments, the hard mask layer 110 is a single layer and includes a silicon germanium layer. In some embodiments, the hard mask layer 110 is a multi-layer and includes a silicon nitride layer and a silicon oxide layer over the silicon nitride layer. In some other embodiments, the hard mask layer 110 is a multi-layer and includes a silicon germanium layer and a silicon layer over the silicon germanium layer.

As shown in FIG. 6, each of the fins 112 includes a base fin (102-1, 102-2, and 102-3) formed from a portion of the substrate 102 and a stack portion formed from the stack 104 over the base portion. In some aspects, the base fins 102-1 to 102-3 protrude from the substrate 102. Each of the fins 112 may include the semiconductor layers 106 and 108 alternating stacked in the Z-direction. The fins 112 extend lengthwise (e.g., longitudinally) in the X-direction, extend vertically in the Z-direction over the substrate 102, and are arranged in the Y-direction, as shown in FIG. 6. In some embodiments, widths of the fins 112 in the Y-direction are the same. Although three fins 112 are formed and shown herein, less or more fins may be formed, such as two or more fins.

The fins 112 may be patterned using suitable processes including double-patterning or multi-patterning processes. For example, in some embodiments, a material layer of the hard mask layer 110 is formed over the substrate 102 and patterned into the hard mask layer 110 using a photolithography process. One or more etching processes are then performed to etch the stack 104 and top portions of the substrate 102 not covered by the hard mask layer 110 to form the fins 112. The etching process may include dry etching, wet etching, reactive ion etching (RIE), and/or other suitable processes.

Referring to FIG. 7, isolation features 114 are formed over the substrate 102. More specifically, after the fins 112 are formed, the hard mask layer 110 over the fins 112 is removed and the isolation features 114 are then formed over the substrate 102. In some embodiments, the isolation structures 114 are formed between the fins 112. In some aspects, the isolation features 114 are formed around the fins 112. More specifically, the isolation structures 114 are formed between and around the base fins (e.g., 102-1, 102-2, and 102-3) of the fins 112. In other aspects, the isolation features 114 are formed on opposite sides of the fins 112 (semiconductor layers 106 and 108) in the Y-direction. The isolation features 114 may be shallow trench isolation (STI) features that provide electrical isolation between the different GAA transistors, in accordance with some embodiments. As such, the isolation features 114 may also be referred to as STI features.

In some embodiments, a dielectric material for the isolation features 114 are first deposited over the workpiece 100. Specifically, the dielectric material is deposited and formed over the fins 112 and the substrate 102 to cover the fins 112 and the substrate 102. In some aspects, the dielectric material is formed to wrap around the fins 112. In some embodiments, the dielectric material may include silicon oxide, silicon nitride, silicon oxynitride, silicon carbide, borosilicate glass (BSG), phosphoric silicate glass (PSG), borophosphosilicate glass (BPSG), fluorine-doped silicate glass (FSG), a low-k dielectric (e.g., a carbon doped oxide, SiCOH), combinations thereof, and/or other suitable materials. In various embodiments, the dielectric material may be deposited by a CVD, a subatmospheric CVD (SACVD), a plasma-enhanced CVD (PECVD), a flowable CVD (FCVD), an ALD, a plasma-enhanced ALD (PEALD), spin-on coating, and/or other suitable process. The deposited dielectric material is then thinned and planarized, for example by a chemical mechanical polishing (CMP) process, until top surfaces of the hard mask layer 110 is exposed (not shown). The planarized dielectric material is further recessed by a dry etching process, a wet etching process, and/or a combination thereof to form the isolation features 114.

In some embodiments, the isolation features 114 may have a multi-layer structure such as a thermal oxide liner layer over the substrate 102 and a filling layer (e.g., silicon nitride or silicon oxide) over the thermal oxide liner layer. In some embodiments, before the formation of the isolation features 114, a liner layer may be conformally deposited over the substrate 102 using ALD or CVD. Furthermore, as shown in FIG. 7, the stack portions of the fins 112 rise above the isolation features 114 while the base fins 102-1 to 102-3 are surrounded by the isolation features 114. In some embodiments, top surfaces (or topmost surfaces) of the substrate 102 is higher than top surfaces of the isolation features 114. In other words, the top surfaces of the isolation features 114 are lower than the top surfaces (or the topmost surfaces) of the substrate 102.

Referring to FIG. 8, dummy gate structures 116-1 to 116-3 (may be collectively referred to as dummy gate structures 116) may be formed over the fins 112, the isolation feature 114, and the substrate 102. The dummy gate structures 116 may be configured to extend lengthwise in the Y-direction and wrap around top surfaces and side surfaces of the fins 112, as shown in FIG. 8 (not shown in FIG. 8, but may refer to gate structures replacing the dummy gate structures 116 in FIG. 16A). In some embodiments, to form the dummy gate structures 116, a dummy interfacial material of a dummy interfacial layer 118 is first formed over the fins 112 and over the isolation features 114.

In some embodiments, the dummy interfacial layer 118 may include, for example, a dielectric material such as a nitride (e.g., silicon nitride, silicon oxynitride), a carbide (e.g., silicon carbide), an oxide (e.g., silicon oxide), or some other suitable material. Then, in some embodiments, a dummy gate material of a dummy gate electrode 120 is formed over the dummy interfacial material. The dummy gate material may include a conductive material selected from a group comprising of polysilicon, W, Al, Cu, AlCu, Ti, TiAlN, TaC, TaCN, TaSiN, Mn, Zr, TiN, Ta, TaN, Co, Ni, and/or combinations thereof. The dummy gate material and/or the dummy interfacial material may be formed by way of a thermal oxidation process and/or a deposition process (e.g., PVD, CVD, PECVD, and ALD).

In some embodiments, hard mask layers may be formed over the dummy gate material. In some embodiments, the hard mask layers may be formed using photolithography and removal (e.g., etching) processes. In some embodiments, the hard mask layers may include photoresist materials or hard mask materials. In some embodiments, each of the hard mask layers may include multiple layers, such as a silicon nitride layer and a silicon oxide layer. After the formation of the hard mask layers, a removal process (e.g., etching) may be performed to remove portions of the dummy gate material for the dummy gate electrodes 120 that do not directly underlie the hard mask layers, thereby forming the dummy gate structures 116 each having the dummy interfacial layer 118, the dummy gate electrode 120, and the hard mask layer. The dummy interfacial layers 118 may also be referred to as dummy gate dielectrics. The dummy gate structures 116 may undergo a gate replacement process through subsequent processing to form metal gates, such as a high-k metal gate, as discussed in greater detail below.

FIG. 8 shows three dummy gate structures 116-1 to 116-3. In some embodiments, less or more dummy gate structures may be formed for one or more transistors sharing source/drain regions. In other embodiments, some dummy gate structures may also undergo a gate replacement process to form dielectric based gates that electrically isolate transistors formed by the dummy gate structure 116 from neighboring transistors or devices. For examples, dummy gate structures 116-1 and 116-3 may be replaced with dielectric material in sequent processes to form dielectric based gates to isolate resultant transistor formed from the dummy gate structure 116-2 from neighboring transistors or devices.

Still referring to FIG. 8, after the formation of the dummy gate structures 116, the hard mask layers are removed and gate spacers 122 are formed on the sidewalls of the dummy gate structures 116, over top surfaces of the fins 112, and on sidewalls of the fins 112 (not shown). More specifically, the gate spacers 122 are formed on opposite sidewalls of the fins 112 in the Y-direction (not shown) and formed on opposite sides (or sidewalls) of the dummy gate structures 116 in the X-direction, as shown in FIG. 8.

The gate spacers 122 may include silicon nitride (Si₃N₄), silicon oxide (SiO₂), silicon carbide (SiC), silicon oxycarbide (SiOC), silicon oxynitride (SiON), silicon oxycarbon nitride (SiOCN), carbon doped oxide, nitrogen doped oxide, porous oxide, or combinations thereof. The gate spacers 122 may include a single layer or a multi-layer structure. In some embodiments, the gate spacers 122 may be formed by conformally depositing a spacer layer (containing the dielectric material) over the isolation features 114, the fins 112, and dummy gate structures 116, followed by an anisotropic etching process to remove top portions of the spacer layer from the top surfaces of the isolation features 114, the fins 112, and dummy gate structures 116. After the etching process, portions of the spacer layer on the sidewall surfaces of the fins 112 (not shown) and the dummy gate structures 116 substantially remain and become the gate spacers 122. In some embodiments, the anisotropic etching process is a dry (e.g., plasma) etching process. Additionally or alternatively, the formation of the gate spacers 122 may also involve chemical oxidation, thermal oxidation, ALD, CVD, and/or other suitable methods.

The gate spacers 122 may also be interchangeably referred to as the top spacers. In sequent processes discussed in below, the gate spacers 122 will be removed and replaced with other gate spacers. Therefore, the gate spacers 122 may also be referred to as sacrificial gate spacers, in accordance with some embodiments.

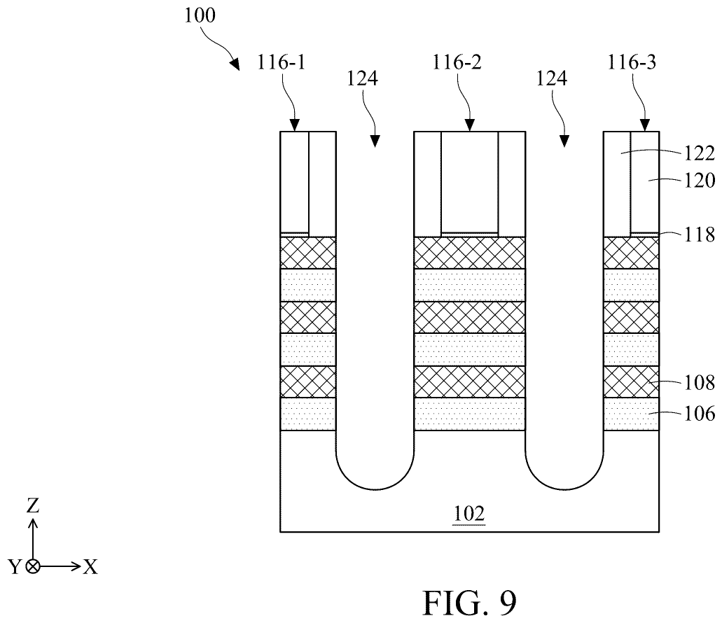

Referring to FIG. 9, the fins 112 are recessed to form source/drain trenches 124 in the fins 112 (or passing through the semiconductor layers 106 and 108) exposed by the dummy gate structures 116. More specifically, the source/drain trenches 124 may be formed by performing one or more etching processes to remove portions of the semiconductor layers 106, the semiconductor layers 108, and the substrate 102 that do not vertically overlap or be covered by the dummy gate structures 116 and gate spacers 122. In some embodiments, a single etchant may be used to remove the semiconductor layers 106, the semiconductor layers 108, and the substrate 102, whereas in other embodiments, multiple etchants may be used to perform the etching process. As shown in FIG. 9, portions of the substrate 102 are etched so that the substrate 102 has concave surfaces, and the concave surfaces are lower than the top surfaces of the isolation features 114 (not shown).

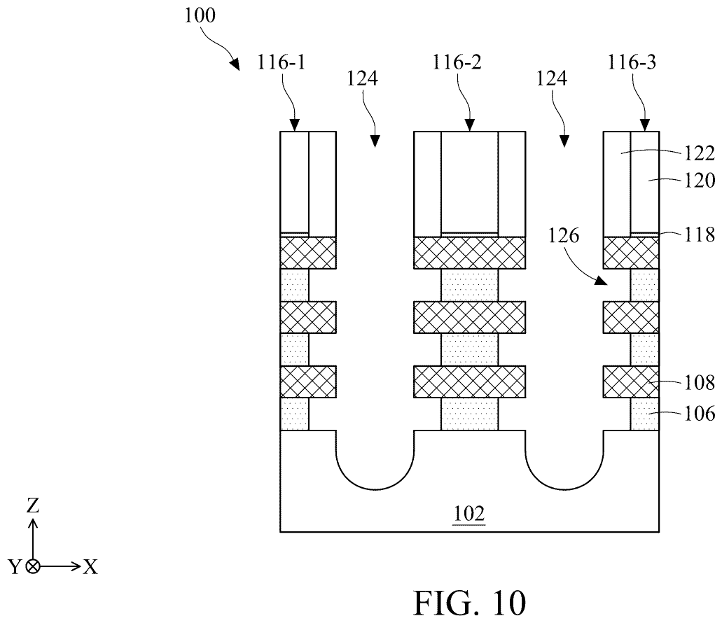

Referring to FIG. 10, side portions of the semiconductor layers 106 are removed via a selective etching process. More specifically, the selective etching process is performed that selectively etches the side portions of the semiconductor layers 106 below the gate spacers 122 through the source/drain trenches 124, with minimal (or no) etching of semiconductor layers 108, the gate spacers 122, and the substrate 102, such that gaps 126 are formed vertically between (the side portions of) the semiconductor layers 108 in the Z-direction as well as vertically between (the side portions of) the semiconductor layers 108 and the substrate 102 in the Z-direction, and below the gate spacers 122. The etching process is configured to laterally etch (e.g., along the X-direction) the semiconductor layers 106 below the gate spacers 122. The selective etching process is a dry etching process, a wet etching process, other suitable etching process, or combinations thereof.

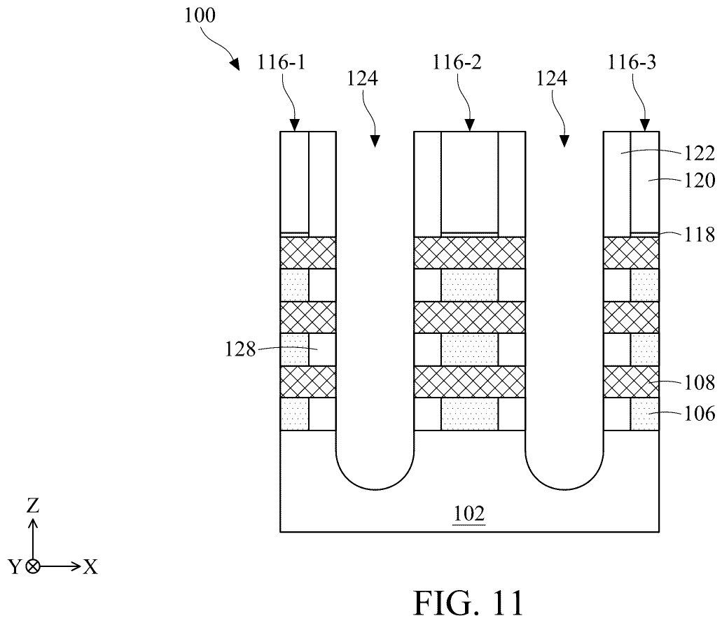

Referring to FIG. 11, inner spacers 128 are formed to fill the gaps 126. The inner spacers 128 are between the semiconductor layers 108 in the Z-direction and between the (bottommost) semiconductor layers 108 and the substrate 102 direct under the gate spacers 122 in the Z-direction. In some embodiments, sidewalls of the inner spacers 128 are aligned to the sidewalls of the gate spacers 122 and the semiconductor layers 108, as shown in FIG. 11. In order to form the inner spacers 128, a deposition process forms a spacer layer into the source/drain trenches 124 and the gaps 126, such as CVD, PVD, ALD, HDPCVD, MOCVD, RPCVD, PECVD, LPCVD, ALCVD, APCVD, other suitable methods, or combinations thereof. The spacer layer partially (and, in some embodiments, completely) fills the source/drain trenches 124. The deposition process is configured to ensure that the spacer layer fills the gaps 126 between the semiconductor layers 108 as well as between the semiconductor layer 108 and the substrate 102 under the gate spacers 122. An etching process is then performed that selectively etches the spacer layer to form inner spacers 128 (as shown in FIG. 11) with minimal (to no) etching of the semiconductor layer 108, the substrate 102, the dummy gate structure 116, and the gate spacers 122. In sequent processes discussed in below, the inner spacers 128 will be removed and replaced with other inner spacers. Therefore, the inner spacers 128 may also be referred to as sacrificial inner spacers, in accordance with some embodiments.

The spacer layer (and thus inner spacers 128) includes a material that is different than a material of the semiconductor layers 108 and a material of the gate spacers 122 to achieve desired etching selectivity during the etching process. In some embodiments, the inner spacers 128 include a dielectric material that includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN)). In some embodiments, the inner spacers 128 include a low-k dielectric material, such as those described herein.

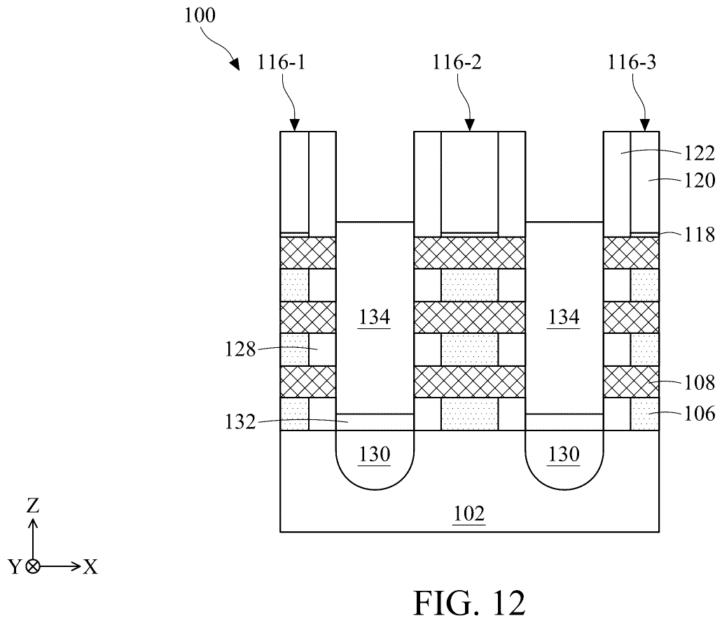

Referring to FIG. 12, silicon layers 130 are formed over the substrate 102 in the source/drain trenches 124. As shown in FIG. 12, the silicon layers 130 are also formed on opposite sides of the dummy gate structures 116 (e.g., the dummy gate structure 116-2), the semiconductor layers 108, and the semiconductor layers 106. In some embodiment, top surfaces of the silicon layers 130 are substantially level with the top surfaces of the substrate 102 and the bottommost surfaces of the semiconductor layers 106 (more specifically, the bottommost semiconductor layer 106), in the X-Z cross-sectional view, as shown in FIG. 12. In some embodiments, the top surfaces of the silicon layers 130 are lower than bottommost surfaces of the semiconductors 106. In some embodiment, the silicon layers 130 each has a convex bottom surface due to the concave surfaces of the substrate 102 in the source/drain trenches 124 discussed above.

The silicon layers 130 are made of silicon without dopants. In other word, the silicon layers 130 are un-doped silicon, and thus may be referred to as un-doped silicon layers. As such, the leakage current of the resultant transistors from one source/drain feature to another source/drain feature through the substrate 102 is prevented, thereby improving performances of the resultant transistors. One or more epitaxy processes may be performed to form the silicon layers 130. Epitaxy processes may implement CVD deposition techniques (for example, vapor-phase epitaxy (VPE), UHVCVD, LPCVD, and/or PECVD), molecular beam epitaxy, other suitable SEG processes, or combinations thereof.

Still referring to FIG. 12, bottom dielectric layers 132 are formed over the silicon layers 130 and the substrate 102 in the source/drain trenches 124. In some embodiment, the bottom dielectric layers 132 is in contact with the sidewalls of the inner spacers 128 in the X-direction, in the X-Z cross-sectional view, as shown in FIG. 12. In some aspect, the bottom dielectric layers 132 is in contact with and between the inner spacers 128 in the X-direction, in the X-Z cross-sectional view. In some embodiments, the top surfaces of the bottom dielectric layers 132 are higher than topmost surfaces of the substrate 102 to ensure that the bottom dielectric layers 132 separate the source/drain features 134 (will be discussed below) from the silicon layers 130 and the substrate 102. In some embodiments, top surfaces of the bottom dielectric layers 132 are lower than bottommost surfaces of the semiconductor layers 108, as shown in FIG. 12.

In some embodiments, the dielectric material of the bottom dielectric layers 132 may include silicon nitride (Si₃N₄), silicon oxide (SiO₂), silicon carbide (SiC), silicon oxycarbide (SiOC), silicon oxynitride (SiON), silicon carbon nitride (SiCN), silicon oxycarbon nitride (SiOCN), other suitable material(s), or combinations thereof, and may be deposited by CVD, PVD, ALD, HDPCVD, MOCVD, RPCVD, PECVD, LPCVD, ALCVD, APCVD, other suitable methods, or combinations thereof. It should be noted that the source/drain features 134 are separated from the silicon layers 130 and the substrate 102 by the bottom dielectric layers 132. As such, it prevents the leakage current of the resultant transistors from one source/drain feature to another source/drain feature through the substrate 102, thereby improving performances of the resultant transistors.

Still referring to FIG. 12, source/drain features 134 are formed in the source/drain trenches 124 and over the bottom dielectric layers 132, the silicon layers 130, and the substrate 102, so that the source/drain features 134 pass through the semiconductor layers 108 and are in the fins 112. The source/drain features 134 are also formed on opposite sides of the dummy gate structures 116 in the X-direction. For example, the source/drain features 134 are formed on opposite sides of the dummy gate structure 116-2 in the X-direction, as shown in FIG. 12. Furthermore, the source/drain features 134 are disposed on opposite sides of the semiconductor layers 108 in the X-direction. The source/drain features 134 are connected to and in contact with the semiconductor layers 108. More specifically, the source/drain features 134 are attached and electrically connected to the semiconductor layers 108 in the X-direction. As shown in FIG. 12, the source/drain features 134 are also in contact with the inner spacers 128, but are electrically isolated from the inner spacers 128. In some aspects, the inner spacers 128 are disposed between the source/drain features 134 and the dummy gate structures 116 in the X-direction. Furthermore, the silicon layers 130 are between the source/drain features 134 and the substrate 102 in the Z-direction. The bottom dielectric layers 132 are between the source/drain features 134 and the silicon layers 130 in the Z-direction. In some aspect, the bottom dielectric layers 132 and the silicon layers 130 are under the source/drain features 134 and over the substrate 102. More specifically, the silicon layers 130 are vertically between and in contact with the bottom dielectric layers 132 and the substrate 102 in the Z-direction and the bottom dielectric layers 132 are vertically between and in contact with the source/drain features 134 and the silicon layers 130 in the Z-direction.

In some aspects, the semiconductor layers 108 serve as channels to connect one source/drain feature 134 to the other source/drain feature 134. Therefore, the semiconductor layers 108 may also be referred to as channels, channel layers, or channel members. In some embodiments, in the X-Z cross-sectional view shown in FIG. 12, the source/drain features 134 may have top surfaces that extend higher than top surfaces of the topmost semiconductor layers 108 (e.g., in the Z-direction), as shown in FIG. 12. In some embodiments, in the X-Z cross-sectional view shown in FIG. 12, the source/drain features 134 may have the top surfaces that extend higher than bottom surfaces of the dummy interfacial layers 118 (e.g., in the Z-direction). In other embodiments, the top surfaces of the source/drain features 134 are substantially level with the top surfaces of the topmost semiconductor layers 108 (i.e., substantially coplanar).

One or more epitaxy processes may be employed to grow the source/drain features 134. Epitaxy processes can implement CVD deposition techniques (for example, vapor-phase epitaxy (VPE), UHVCVD, LPCVD, and/or PECVD), molecular beam epitaxy, other suitable SEG processes, or combinations thereof. The source/drain features 134 may include any suitable semiconductor materials. For example, the source/drain features 134 used for n-type GAA transistors may include epitaxially-grown material selected from a group consisting of silicon phosphide (SiP), silicon carbide (SiC), silicon phosphoric carbide (SiPC), silicon arsenide (SiAs), silicon (Si), or a combination thereof. In some embodiments, the epitaxially-grown material of the source/drain features 134 may be doped with n-type dopants (such as phosphorus, arsenic, other n-type dopant, or combinations thereof) having a doping concentration in a range from about 2×10¹⁹/cm³ to 3×10²¹/cm³. In some embodiments, the source/drain features 134 for n-type GAA transistors may respectively be referred to as n-type source/drain features.

The source/drain features 134 used for p-type GAA transistors may include epitaxially-grown material selected from a group consisting of boron-doped SiGe, boron-doped SiGeC, boron-doped Ge, boron-doped Si, boron and carbon doped SiGe, or a combination thereof. In some embodiments, the epitaxially-grown material of the source/drain features 134 may be doped with p-type dopants (such as boron, indium, other p-type dopant, or a combination thereof) having a doping concentration in a range from about 1×10¹⁹/cm³ to 6×10²⁰/cm³. In some embodiments, the source/drain features 134 for p-type GAA transistors may respectively be referred to as p-type source/drain features.

The source/drain features 134 may also be referred to as source/drain, or source/drain regions. In some embodiments, source/drain feature(s) 134 may refer to a source or a drain, individually or collectively dependent upon the context. The source/drain features 134 may be doped in-situ or ex-situ. One or more annealing processes may be performed to activate the dopants in the source/drain features 134. The annealing processes may include rapid thermal annealing (RTA) and/or laser annealing processes.

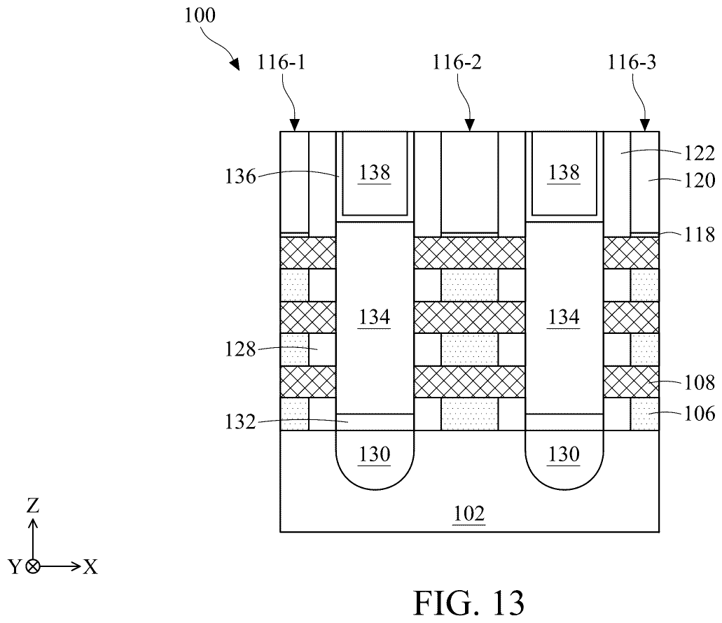

Referring to FIG. 13, a contact etch stop layer (CESL) 136 over the source/drain features 134 and an interlayer dielectric (ILD) layer 138 over the CESL 136 are formed to fill the spaces between the gate spacers 122 and in the source/drain trenches 124. Specifically, the CESL 136 is conformally formed on the sidewalls of the gate spacers 122, over the top surfaces of the source/drain features 134, as shown in FIGS. 13. The ILD layer 138 is then formed over the CESL 136 to fill a remaining space between (or inside) the CESL 136, between the gate spacers 122 and in the source/drain trenches 124.

The CESL 136 includes a material that is different than ILD layer 138. The CESL 136 may include La₂O₃, Al₂O₃, SiOCN, SiOC, SiCN, SiO₂, SiC, ZnO, ZrN, Zr₂Al₃O₉, TiO₂, TaO₂, ZrO₂, HfO₂, Si₃N₄, Y₂O₃, AlON, TaCN, ZrSi, or other suitable material(s); and may be formed by CVD, PVD, ALD, or other suitable methods. The ILD layer 138 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD 138 may be formed by PECVD (plasma enhanced CVD), FCVD (flowable CVD), or other suitable methods.

Subsequent to the deposition of the CESL 136 and the ILD layer 138, a CMP process and/or other planarization process is performed on the CESL 136 and the ILD layer 138 until the top surfaces of the dummy gate electrodes 116 and the gate spacers 122 are exposed. In some embodiments, portions of the dummy gate electrodes 116 are removed after the planarization process. In some embodiments, the ILD layer 138 is recessed to a level below the top surface of the dummy gate electrode 116, and then an ILD protection layer is formed over the ILD layer 138 to protect the ILD layer 138 from subsequent etching processes. As such, the ILD layer 138 is surrounded by the CESL 136 and the ILD protection layer. In some embodiments, the ILD protection layer includes a material that is the same as or similar to that in the CESL 136. In some other embodiments, the ILD protection layer includes a dielectric material such as Si₃N₄, SiCN, SiOCN, SiOC, a metal oxide such as HrO₂, ZrO₂, hafnium aluminum oxide, hafnium silicate, or other suitable material, and may be formed by CVD, PVD, ALD, or other suitable methods.

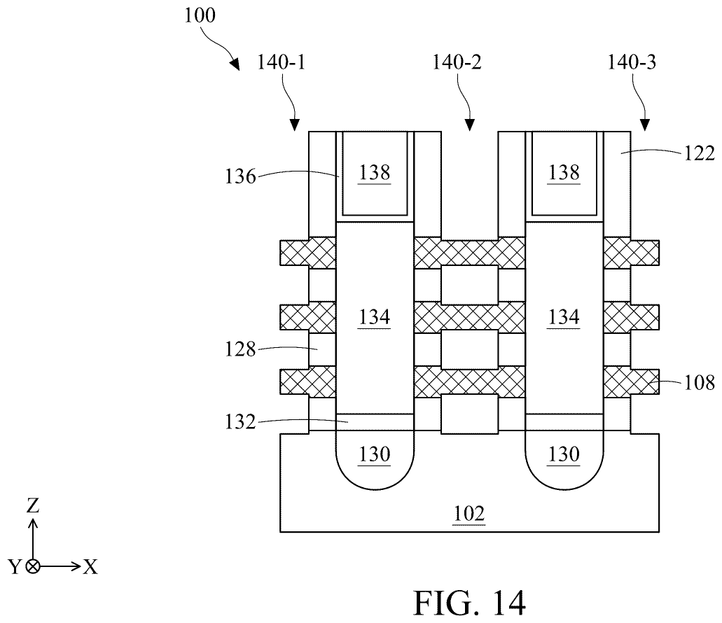

Referring to FIG. 14, the dummy gate structures 116 are selectively removed through any suitable lithography and etching processes to form gate trenches 140 (including gate trenches 140-1 to 140-3). In some embodiments, the lithography process may include forming a photoresist layer (resist), exposing the resist to a pattern, performing a post-exposure bake process, and developing the resist to form a masking element, which exposes a region including the dummy gate structures 116. Then, the dummy gate structures 116 are selectively etched through the masking element. The gate spacers 122 may be used as the masking element or a part thereof. Etch selectivity may be achieved by selecting the appropriate etching chemicals, and the dummy gate structures 116 may be removed without substantially affecting the CESL 136 and the ILD layer 138. The removal of the dummy gate structures 116 creates the gate trenches 140-1 to 140-3, in which the gate trenches 140-1 to 140-3 expose the top surfaces of the fins 112 (specifically, the top surfaces of the topmost semiconductor layers 108).

Still referring to FIG. 14, the semiconductor layers 106 of the fins 112 are selectively removed through the gate trenches 140, using a wet or dry etching process for example, so that middle portions of the semiconductor layers 108 are exposed in the gate trenches 140 to form nanostructures stacked over each other, which serving as channels, channel layers, or channel members for resultant transistors. As such, the semiconductor layers 108 may be referred to as nanostructures. Specifically, the semiconductor layers 108 are stacked over each other in the Z-direction. Such a process may also be referred to as a release process, a channel release process, a wire release process, a nanowire release process, a nanosheet release process, a nanowire formation process, a nanosheet formation process, or a wire formation process.

In some embodiments, the removal of the semiconductor layers 106 causes the exposed semiconductor layers 108 to be spaced apart from each other in the vertical direction (e.g., in the Z-direction). The exposed semiconductor layers 108 extend longitudinally in the horizontal direction (e.g., in the X-direction). Furthermore, each of the semiconductor layers 108 connects one source/drain feature 134 to another source/drain feature 134 (e.g., shown in FIG. 14). In some embodiments, thicknesses of the semiconductor layers 108 exposed in the gate trenches 140 may be reduced during the removal of the semiconductor layers 106. In other embodiments, heights of the substrate 102 exposed in the gate trenches 146 may also be reduced during the removal of the semiconductor layers 106. As such, each of the semiconductor layers 108 shown in the X-Z cross-sectional views of the FIG. 14 has a dumbbell-like shape.

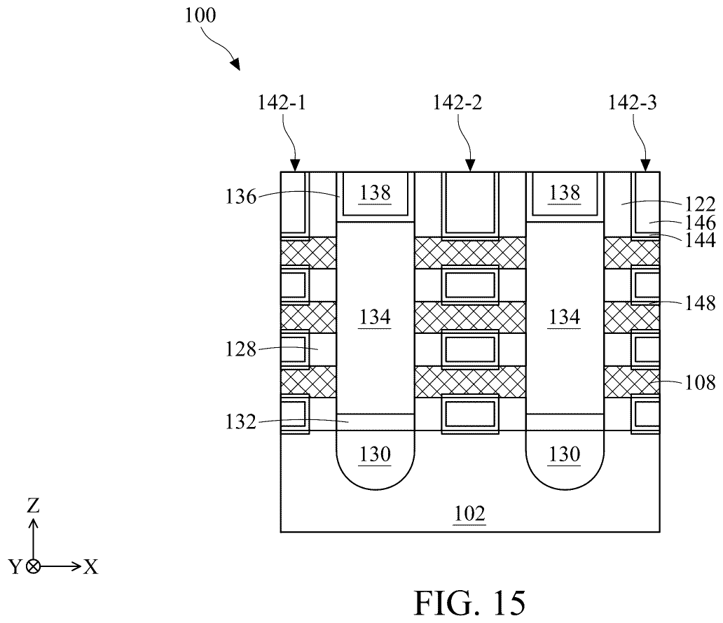

Referring to FIG. 15, gate structures 142 (including gate structures 142-1 to 142-3) are formed in the gate trenches 140 to wrap around the exposed semiconductor layers 108. As such, the gate structures 142 replace the dummy gate structures 116. In some embodiments, the gate structures 142 extend in the Y-direction (not shown in FIG. 15, but may refer to gate structures 142 in FIG. 16A). As shown in FIG. 15, the source/drain features 134 are formed on opposite sides of the gate structure 142-2 in the X-direction. The gate structures 142 each includes a gate dielectric layer 144 and a gate electrode layer 146 over the gate dielectric layer 144. In some embodiments, the gate dielectric layers 146 are formed to wrap around the semiconductor layers 108 in the gate trenches 140. Additionally, the gate dielectric layers 144 also formed on the sidewalls of the inner spacers 128 and the gate spacers 122.

The gate dielectric layers 144 may include a dielectric material having a dielectric constant greater than a dielectric constant of SiO₂, which is approximately 3.9. For example, the gate dielectric layers 144 may include hafnium oxide (HfO₂), which has a dielectric constant in a range from about 18 to about 40. Alternatively, the gate dielectric layers 144 may include other high-K dielectrics, such as TiO₂, HfZrO, Ta₂O₃, HfSiO₄, ZrO₂, ZrSiO₂, LaO, AlO, ZrO, TiO, Ta₂O₅, Y₂O₃, SrTiO₃ (STO), BaTiO₃ (BTO), BaZrO, HfLaO, HfSiO, LaSiO, AlSiO, HfTaO, HfTiO, (Ba,Sr) TiO₃ (BST), Al₂O₃, Si₃N₄, oxynitrides (SiON), combinations thereof, or other suitable material. The gate dielectric layers 144 may be formed by ALD, PVD, CVD, oxidation, and/or other suitable methods.

In some embodiments, the gate structures 142 each may further include interfacial layer 148 formed to wrap around the exposed semiconductor layers 108 before the formation of the gate dielectric layers 144, so that the gate dielectric layers 144 are separated from semiconductor layers 108 by the interfacial layer 148. In some embodiments, the interfacial layer 148 may include a dielectric material such as silicon oxide (SiO₂), HfSiO, or silicon oxynitride (SiON). The interfacial layer 148 may be formed by chemical oxidation, thermal oxidation, ALD, CVD, and/or other suitable method.

The gate electrode layers 146 are formed to fill the remaining spaces of the gate trenches 140, and over the gate dielectric layers 144 in such a way that the gate electrode layers 146 wrap around the semiconductor layers 108, the gate dielectric layers 144, and the interfacial layers 148 (if present). The gate electrode layers 146 each may include a single layer or alternatively a multi-layer structure. In some embodiments, the gate electrode layers 146 each may include a capping layer, a barrier layer, work function metal layers, and a fill material.

The capping layer may be formed adjacent to the gate dielectric layers 144 and may be formed from a metallic material such as TaN, Ti, TiAlN, TiAl, Pt, TaC, TaCN, TaSiN, Mn, Zr, TiN, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The metallic material may be deposited using a deposition process such as ALD, CVD, or the like, although any suitable deposition process may be used.

The barrier layer may be formed adjacent the capping layer, and may be formed of a material different from the capping layer. For example, the barrier layer may be formed of a material such as one or more layers of a metallic material such as TiN, TaN, Ti, TiAlN, TiAl, Pt, TaC, TaCN, TaSiN, Mn, Zr, Ru, Mo, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. The barrier layer may be deposited using a deposition process such as atomic layer deposition, chemical vapor deposition, or the like, although any suitable deposition process may be used.

The gate electrode layers 146 may each has single or multiple work function metal materials. In some embodiments, the gate electrode layers 146 may each has n-type work function metal layers for n-type GAA transistors and p-type work function metal layers for p-type GAA transistors. More specifically, the gate electrode layers 146 may each has n-type work function metal layers between the source/drain features 134 with n-type dopant for n-type GAA transistors and p-type work function metal layers between the source/drain features 134 with p-type dopant for p-type GAA transistors, in accordance with some embodiments of the present disclosure.

The n-type work function metal layer may be formed adjacent to the barrier layer. In an embodiment, the n-type work function metal layer is a material such as Ti, Al, Ag, Mn, Zr, TiAl, TiAlC, TaC, TaCN, TaSiN, TaAl, TaAlC, TiAlN, other suitable n-type work function materials, or combinations thereof. For example, the n-type work function metal layer may be deposited utilizing ALD, CVD, or the like. However, any suitable materials and processes may be utilized to form the n-type work function metal layer.

The p-type work function metal layer may be formed adjacent to the n-type work function metal layer. In an embodiment, the p-type work function metal layer may be a material such as TiN, TaN, Ru, Mo, Al, WN, ZrSi2, MoSi2, TaSi2, NiSi2, WN, other metal oxides, metal nitrides, metal silicates, transition metal-oxides, transition metal-nitrides, transition metal-silicates, oxynitrides of metals, metal aluminates, zirconium silicate, zirconium aluminate, combinations of these, or the like. Additionally, the p-type work function metal layer may be deposited using a deposition process such as ALD, CVD, or the like, although any suitable deposition process may be used.

As shown in FIG. 15, after the formation of the gate dielectric layer 144 and the gate electrode layers 146 for the gate structures 142, a planarization process (e.g., a CMP process) is performed on the gate dielectric layer 144, the gate electrode layers 146, the gate spacers 122, the CESL 136, and the ILD layer 138, such that the heights of the gate dielectric layer 144, the gate electrode layers 146, the gate spacers 122, the CESL 136, and the ILD layer 138 are reduced. Furthermore, top surfaces of the gate structures 142 (on the gate dielectric layer 144 and the gate electrode layers 146), the gate spacers 122, the CESL 136, and the ILD layer 138 are substantially level with each other (i.e., coplanar), as shown in FIG. 15.

Referring to FIGS. 16A to 16C, source/drain contacts 150 are formed. More specifically, as shown in FIGS. 16A and 16B, the source/drain contacts 150 are formed over the source/drain features 134, and passing through the CESL 136 and the ILD layer 138. In some embodiments, portions of the source/drain features 134 is removed during the formation of the source/drain contact 150. The source/drain contacts 150 are electrically connected to (top surfaces of) the source/drain features 134. In some embodiment, dielectric layers 151 are formed on sidewalls of the source/drain contacts 150, as shown in FIG. 16A. The dielectric layers 151 have the same material as the CESL 136 discussed above.

In some embodiment, silicide features are formed between the source/drain contacts 150 and the source/drain features 134 in the Z-direction. The silicide features are also between the adjacent two gate structures 142 in the X-direction. The silicide features may include titanium silicide (TiSi), nickel silicide (NiSi), tungsten silicide (WSi), nickel-platinum silicide (NiPtSi), nickel-platinum-germanium silicide (NiPtGeSi), nickel-germanium silicide (NiGeSi), ytterbium silicide (YbSi), platinum silicide (PtSi), iridium silicide (IrSi), erbium silicide (ErSi), cobalt silicide (CoSi), or other suitable compounds.

The conductive material of the source/drain contacts 150 may include Al, Cu, W, Co, Ti, Ta, Ru, Rh, Ir, Pt, TiN, TiAl, TiAlN, TaN, TaC, combinations of these, or the like, although any suitable material may be deposited using a deposition process such as sputtering, CVD, electroplating, electroless plating, or the like. In some embodiments, the source/drain contacts 150 may include single conductive material layer or multiple conductive layers.

As shown in FIG. 16C, the gate spacers 122 are in contact with the inner spacers 128. Furthermore, the gate spacers 122 are also formed over the isolation features 114. In some embodiments, the gate spacers 122 and the inner spacers 128 are formed to wrap around side portions of the semiconductor layers 108, as shown in FIG. 16C. It is noted that the gate spacers 122 and the inner spacers 128 are formed without air gaps therein. Therefore, the gate spacers 122 and the inner spacers 128 have enough strength and good strain to support the structure and processes for the processes discussed above.

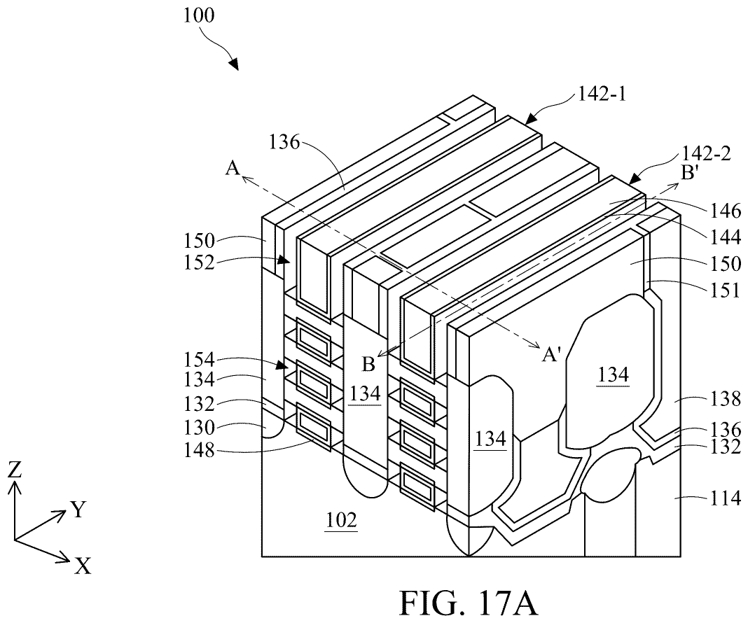

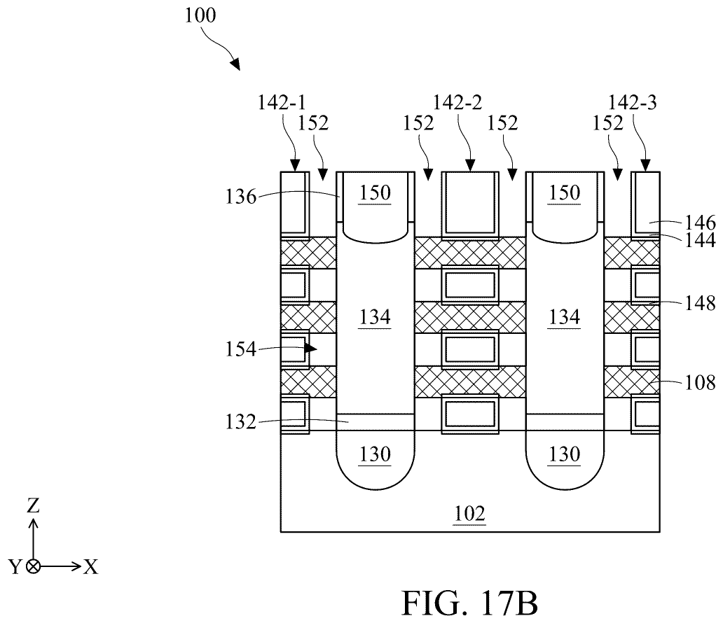

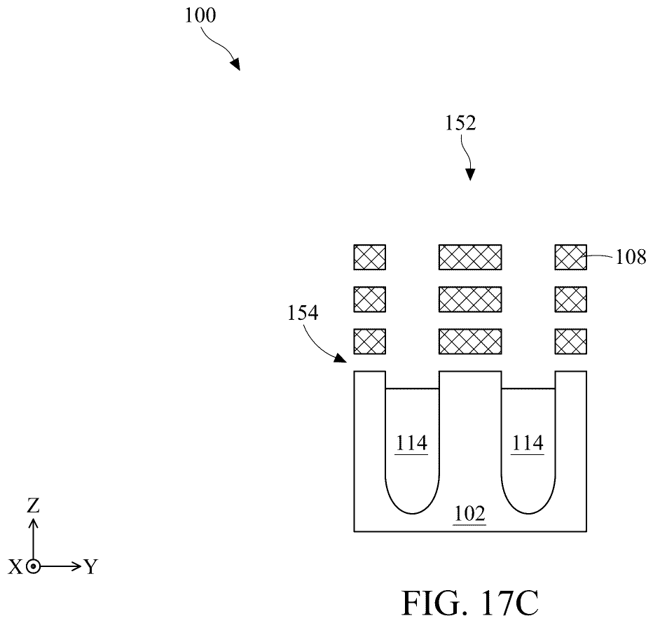

Referring to FIGS. 17A to 17C, the gate spacers 122 and the inner spacers 128 are removed. More specifically, an etching processes is performed to remove the gate spacers 122 and the inner spacers 128. The etching process is a selective etching process that selectively the gate spacers 122 and the inner spacers 128, with minimal (or no) etching of the semiconductor layers 108, the isolation features 114, the gate structures 142 (specifically, the gate dielectric layers 144), the bottom dielectric layers 132, the source/drain features 134, and the substrate 102, such that trenches 152 and gaps 154 are formed. The trenches 152 are over and exposed the isolation features 114 and the semiconductor layers 108. The gaps 154 are vertically between (the side portions of) the semiconductor layers 108 in the Z-direction as well as vertically between (the side portions of) the semiconductor layers 108 and the substrate 102 in the Z-direction. As shown in FIG. 17C, the trenches 152 are connected to the gaps 154, in accordance with some embodiments. The selective etching process is a dry etching process, a wet etching process, other suitable etching process, or combinations thereof.

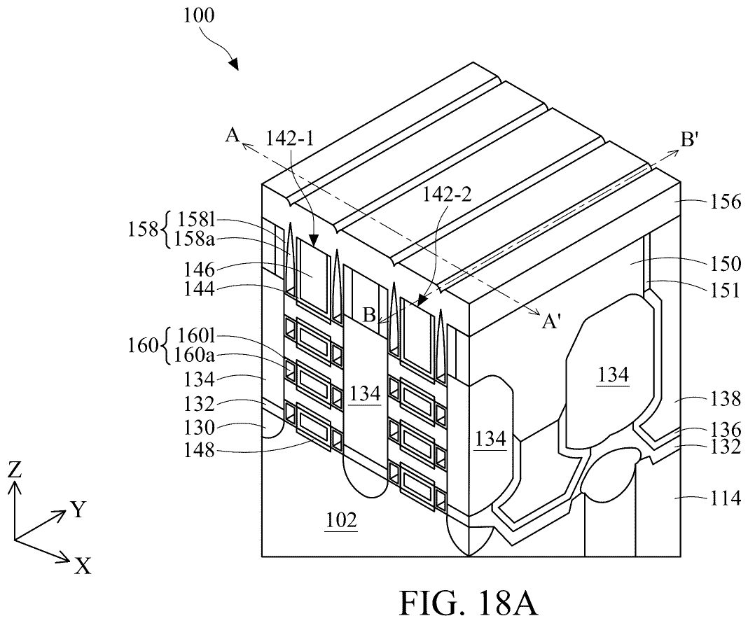

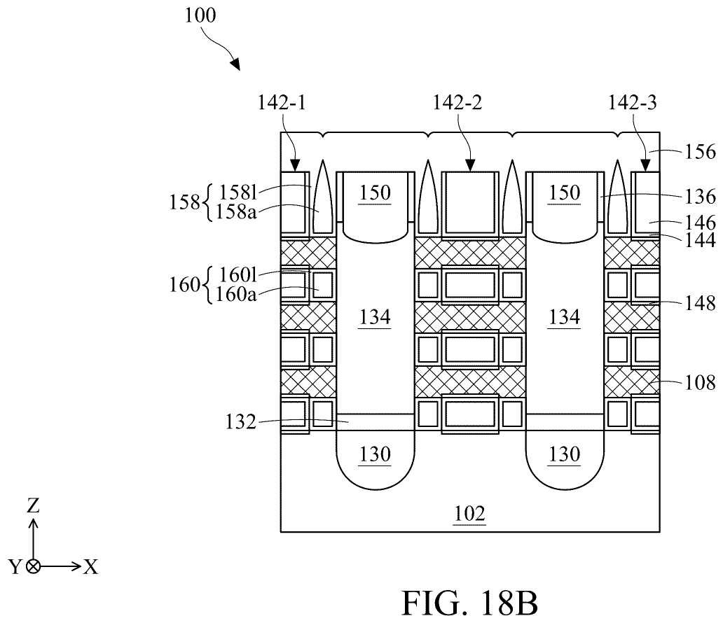

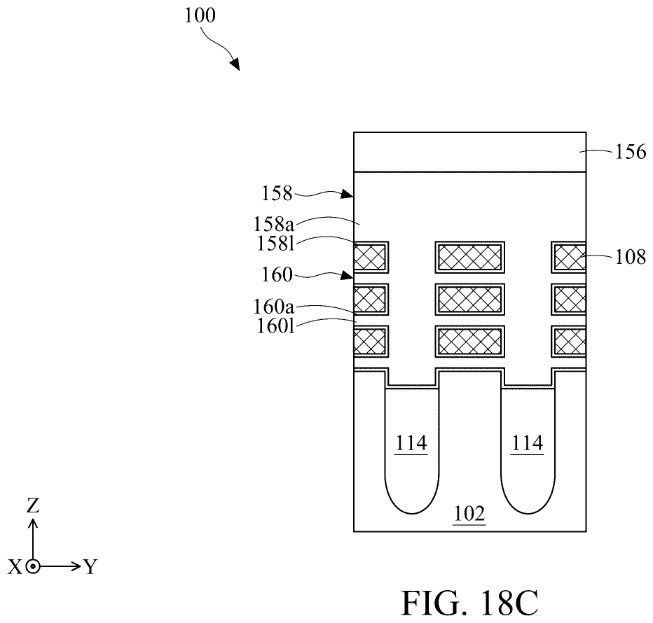

Referring to FIGS. 18A to 18C, a dielectric layer 156 is formed in the trenches 152 and the gaps 154 to form gate spacers 158 and inner spacers 160. As shown in FIGS. 18A to 18C, the gate spacers 158 replace the gate spacers 122 and the inner spacers 160 replace the inner spacers 128. In some embodiments, each of the gate spacers 158 has an air gap 158a and a liner layer 1581 formed of the dielectric layer 156, as shown in FIGS. 18A to 18C. In some aspects, the liner layer 1581 wraps around the air gap 158a to construct the gate spacer 158. Furthermore, each of the inner spacers 160 has an air gap 160a and a liner layer 160l formed of the dielectric layer 156, as shown in FIGS. 18A to 18C. In some aspects, the liner layer 160l wraps around the air gap 160a to construct the inner spacer 160. In other words, the dielectric layer 156 partially fills the trenches 152 and the gaps 154 to form the gate spacers 158 with air gaps 158a and the inner spacers 160 with air gaps 160a. In some embodiments, the bottom dielectric layers 132 are in contact with the inner spacers 160 in the X-direction.

As shown in FIGS. 18A to 18C, each of the air gaps 158a of the gate spacers 158 has a bullet shape in the X-Z cross-sectional view, as shown in FIG. 18A. Furthermore, each of the air gaps 160a of the inner spacers 160 has a rectangular shape in the X-Z cross-sectional view, as shown in FIG. 18A. As shown in FIGS. 18A and 18B, highest points of the air gaps 158a of the gate spacers 158 are higher than top surfaces (specifically, the topmost surfaces) of the gate structures 142. In addition, each of the air gaps 160a of the inner spacers 160 has a width in the X-direction and a thickness in the X-direction, in which the thickness is greater than the width, as shown in FIG. 18B. In some embodiments, the gate spacers 158 are connected with each other due to the gate spacers 158 are formed of one dielectric layer 156, as shown in FIG. 18A. Furthermore, as shown in FIG. 18C, the air gaps 158a of the gate spacers 158 are connected to the air gaps 160a of the inner spacers 160, in accordance with some embodiments. The dielectric layer 156 has a non-planar top surface, as shown in FIG. 18A. In some embodiments, a thickness of the liner layers 1581 and 160l is in a range from about 0.1 nm to about 1 nm. Furthermore, in some embodiments, the width of the air gaps 158a and 160a in the X-direction is in a range from about 1 nm to about 15 nm.

As shown in FIG. 18B, the gate spacers 158 are between the gate structures 142 and source/drain contacts 150 and the inner spacers 160 are between the gate structures 142 and the source/drain features 134. The air gaps 158a of the gate spacers 158 and the air gaps 160a of the inner spacers 160 include air. Such air in the air gaps 158a of the gate spacers 158 and the air gaps 160a of the inner spacers 160 has a low k value about 1. Therefore, the gate spacers 158 with air gaps 158a reduce the parasitic capacitance between the gate structures 142 and source/drain contacts 150, and the inner spacers 160 with air gaps 160a reduce the parasitic capacitance between the gate structures 142 and source/drain features 134, thereby improving the resultant transistors.

If the thickness of the liner layers 1581 and 160l is too large (the thickness is greater than about 1 nm) and/or the width of the air gaps 158a and 160a in the X-direction is too small (the width is less than about 1 nm), the parasitic capacitance cannot be significantly reduced. If the thickness of the liner layers 1581 and 160l is too small (the thickness is less than about 0.1 nm) and/or the width of the air gaps 158a and 160a in the X-direction is too large (the width is greater than about 15 nm), the process stability may be impacted.

In some embodiments, the dielectric layer 156 (and thus the liner layer 1581 of the gate spacers 158 and the liner layer 160l of the inner spacers 160) includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN)).

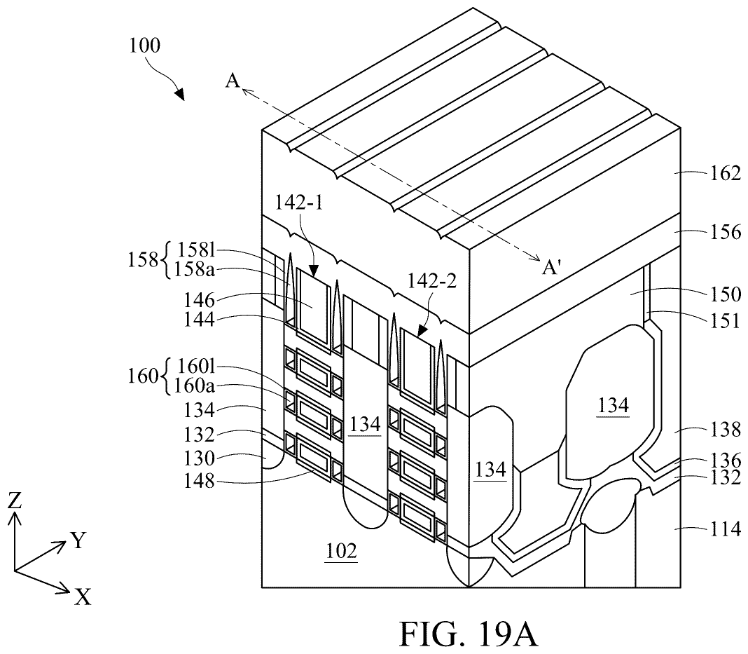

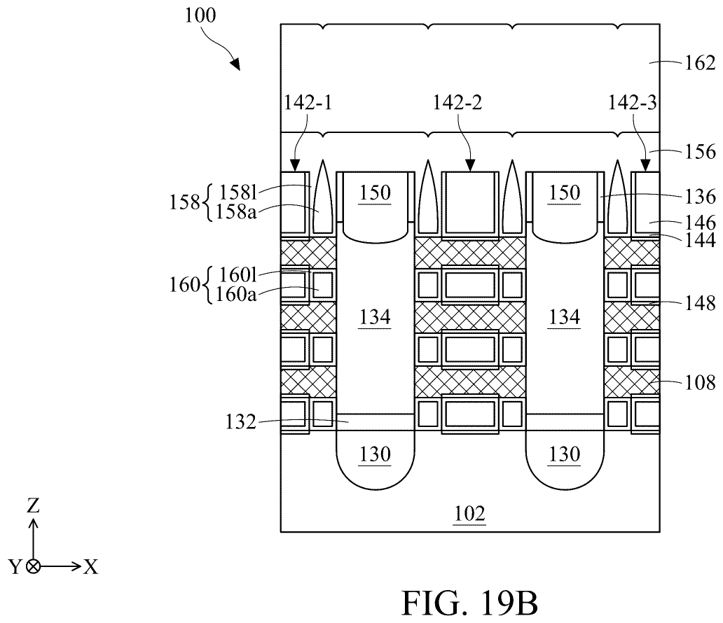

FIGS. 19A and 19B, an ILD layer 162 is formed over the dielectric layer 156 (or the gate spacers 158). The ILD layer 162 may comprise tetraethylorthosilicate (TEOS) formed oxide, un-doped silicate glass, or doped silicon oxide such as borophosphosilicate glass (BPSG), fluoride-doped silica glass (FSG), phosphosilicate glass (PSG), boron doped silicon glass (BSG), a low-k dielectric material, other suitable dielectric material, or combinations thereof. The ILD 162 may be formed by PECVD (plasma enhanced CVD), FCVD (flowable CVD), or other suitable methods.

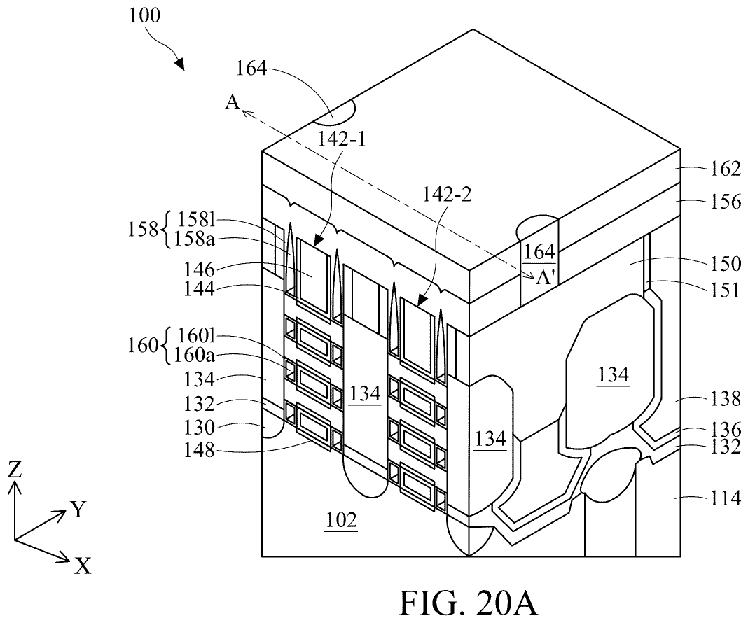

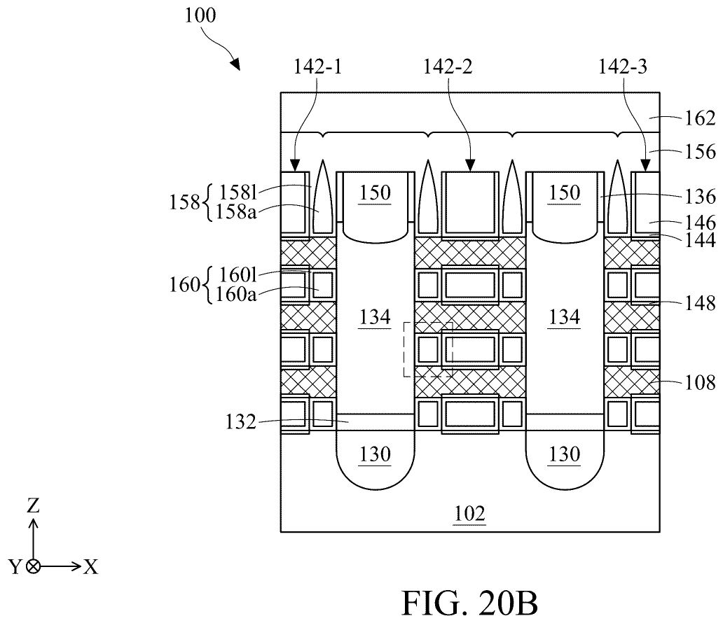

FIGS. 20A and 20B, after the formation of the ILD layer 162, a CMP process and/or other planarization process is performed on the ILD layer 162 to reduce the height of the ILD layer 162. Then, vias 164 are formed passing through the ILD layer 162 and the dielectric layer 156, and is electrically connected to the source/drain contact 150. The materials of the vias 164 are selected from a group consisting of titanium (Ti), titanium nitride (TiN), tantalum (Ta), tantalum nitride (TaN), titanium aluminum nitride (TiAlN), tungsten nitride (WN), tungsten (W), cobalt (Co), molybdenum (Mo), ruthenium (Ru), platinum (Pt), aluminum (Al), copper (Cu), other conductive materials, or a combination thereof. It should be noted that there may be more CESLs, ILD layers in the front-side interconnection structure, and vias and metal lines or conductors therein to form desired circuit routing.

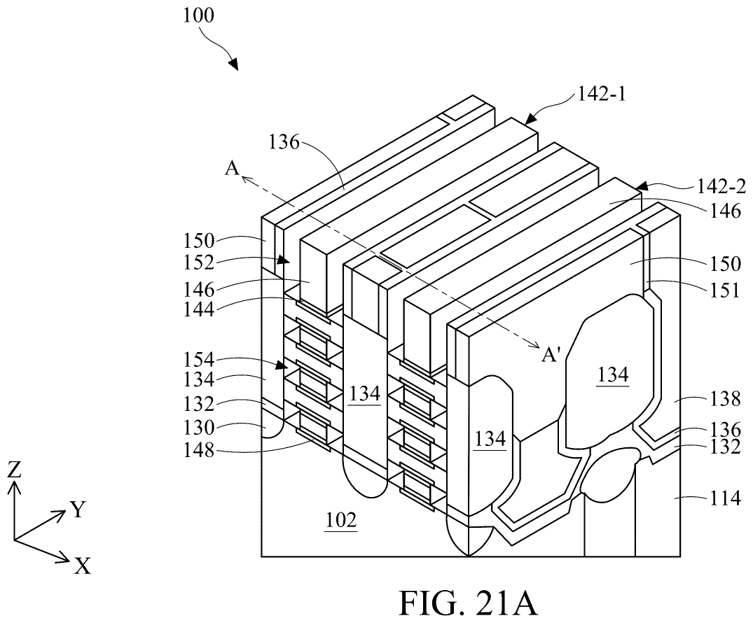

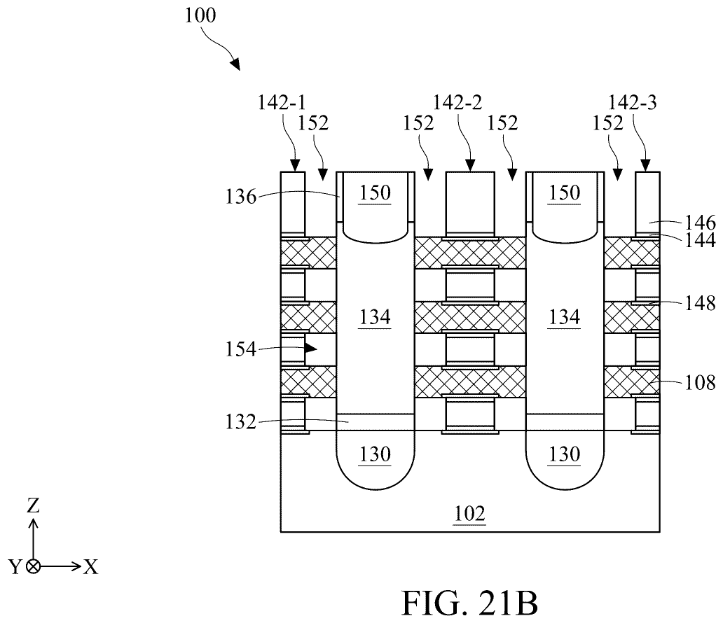

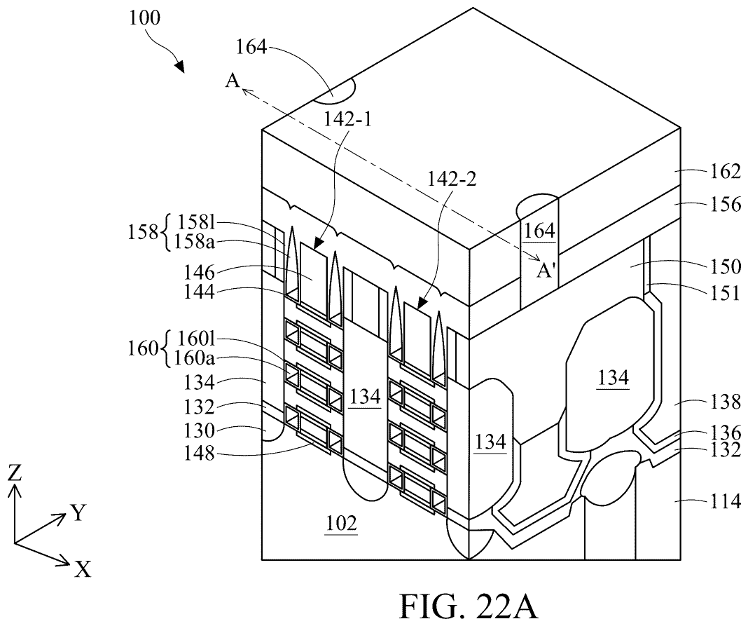

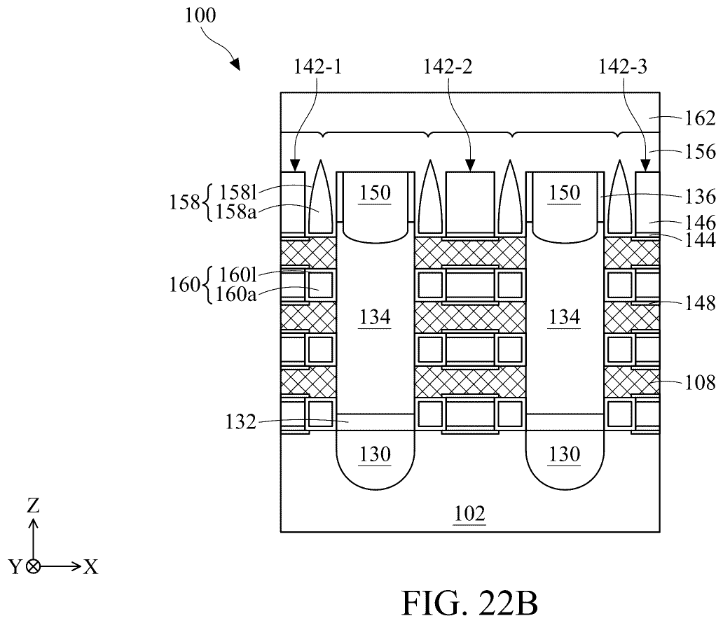

FIGS. 21A and 22A are perspective views of the workpiece 100 at various fabrication stages, in accordance with some alternative embodiments of the present disclosure. FIGS. 21B and 22B are X-Z cross-sectional views of the workpiece 100 at various fabrication stages along lines A-A′ of FIGS. 21A and 22A, respectively, in accordance with some alternative embodiments of the present disclosure.

Referring back to FIG. 20B, the gate spacers 158 and the inner spacers 160 are in contact with the gate structures 142. More specifically, the gate spacers 158 and the inner spacers 160 are in contact with the gate dielectric layers 144 of the gate structures 142. The gate spacers 158 and the inner spacers 160 are separated from the gate electrode layers 146 of the gate structures 142. In some embodiments, the gate spacers 158 and the inner spacers 160 are in contact with the gate electrode layers 146 of the gate structures 142.

Referring to FIGS. 21A and 21B, after the removal of the gate spacers 122 and the inner spacers 128 shown in FIGS. 17A and 17B, the gate dielectric layers 144 of the gate structures 142 on sidewalls of the gate electrode layers 146 of the gate structures 142 in the X-direction are removed. More specifically, an etching processes is performed to remove the gate dielectric layers 144 on the sidewalls of the gate electrode layers 146. The etching process is a selective etching process that selectively the gate dielectric layers 144, with minimal (or no) etching of the semiconductor layers 108, the gate electrode layers 146, the interfacial layers 148, the source/drain features 134, and the substrate 102. Therefore, the sidewalls of the gate electrode layers 146 of the gate structures 142 are exposed in the trenches 152 and the gaps 154, as shown in FIGS. 21A and 21B. Furthermore, as shown in FIGS. 21A and 21B, the interfacial layers 148 are also partially exposed in the trenches 152 and the gaps 154.

Referring to FIGS. 22A and 22B, after the removal of the gate dielectric layers 144 on the sidewalls of the gate electrode layers 146, the dielectric layer 156 (and thus the gate spacers 158 with the air gaps 158a and the inner spacers 160 with the air gaps 160a) and the ILD layer 162 discussed above are formed. As shown in FIGS. 22A and 22B, the gate spacers 158 and the inner spacers 160 are in contact with (the sidewalls of) the gate electrode layers 146 of the gate structures 142. Furthermore, in some embodiments, the gate spacers 158 and the inner spacers 160 are also in contact with the interfacial layers 148. The gate dielectric layers 144 generally have higher k value. Due to the gate dielectric layers 144 on the sidewalls of the gate electrode layers 146 are removed, the parasitic capacitance between the gate structures 142 and source/drain contacts 150 and the parasitic capacitance between the gate structures 142 and source/drain features 134 are further reduced, thereby improving the resultant transistors.

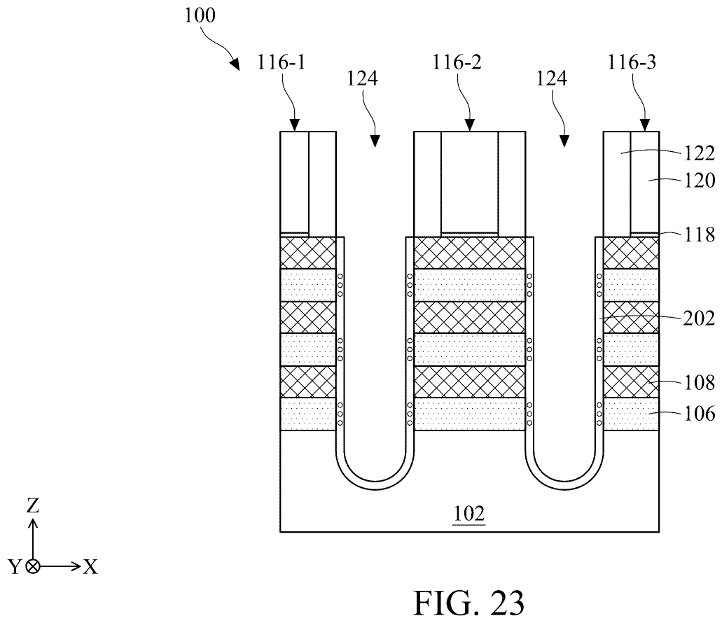

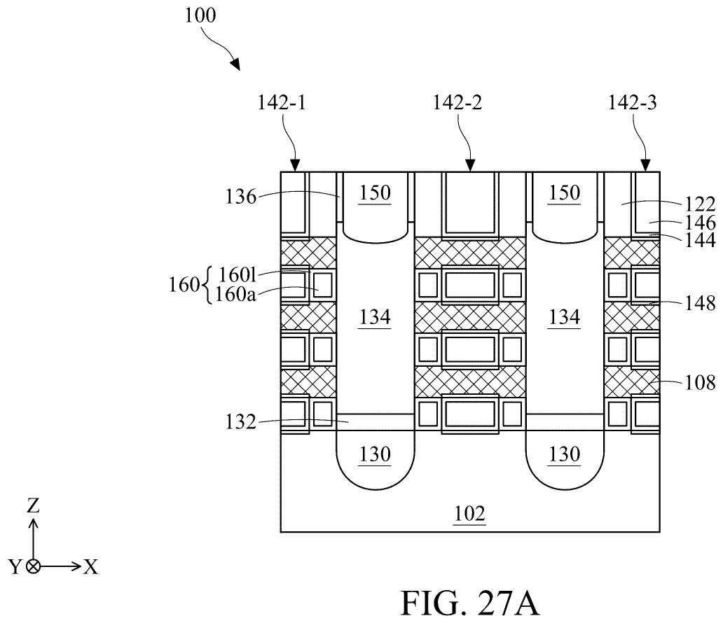

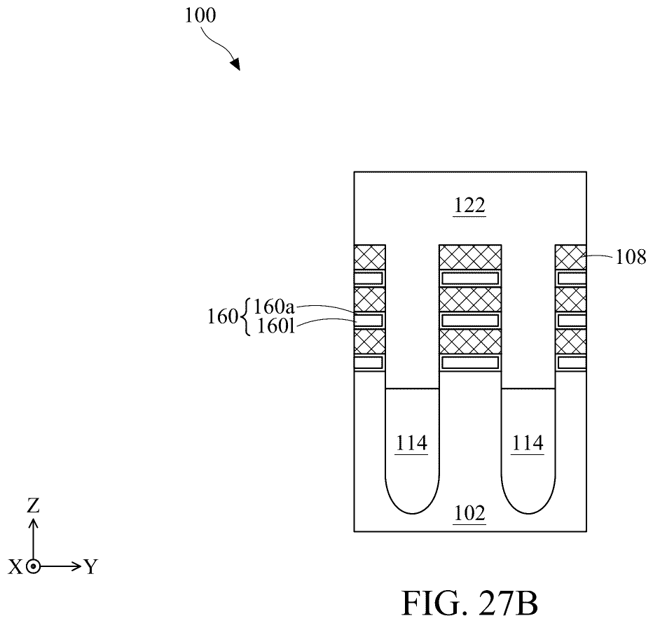

FIGS. 23, 24, 25, 26, 27A, 28A, and 29A are X-Z cross-sectional views of the workpiece 100 at various fabrication stages, in accordance with some alternative embodiments of the present disclosure. FIGS. 27B, 28B, and 29B are Y-Z cross-sectional views of the workpiece 100 at various fabrication stages along lines C-C′ of FIGS. 27A, 28A, and 29A, respectively, in accordance with some alternative embodiments of the present disclosure.

As discussed above, the gate spacers 158 with the air gaps 158a and the inner spacers 160 with the air gaps 160a are formed at the same process stage shown in FIGS. 18A to 18C. FIGS. 23 to 29B shows the gate spacers with air gaps and the inner spacers with air gaps are formed at different stages. Referring to FIG. 23, after the formation of the source/drain trenches 124, oxide layers 202 are formed in the source/drain trenches 124. More specifically, the oxide layers 202 are formed on the sidewalls of the semiconductor layers 106 and 108 in the X-direction and the top surfaces of the substrate 102 exposed in the source/drain trenches 124. The oxide layers 202 are epitaxially grown from the sidewalls of the semiconductor layers 106 and 108 and the top surfaces of the substrate 102 using epitaxial growth, vapor-phase epitaxy (VPE), molecular beam epitaxy (MBE), a combination thereof, or the like. The oxide layers 202 include silicon oxide, in accordance with some embodiments. Therefore, the oxide layers 202 may also be referred to as silicon oxide layers. It is noted that the oxide layers 202 on the sidewalls of the semiconductor layers 106 have some small holes therein due to the different compositions of the semiconductor layers 106 and 108, as shown in FIG. 23. For example, as discussed above, the semiconductor layers 106 may be formed of silicon germanium (SiGe), in accordance with some embodiments. Such semiconductor layers 106 may induce the oxide layers 202 on the semiconductor layers 106 to have the small holes.

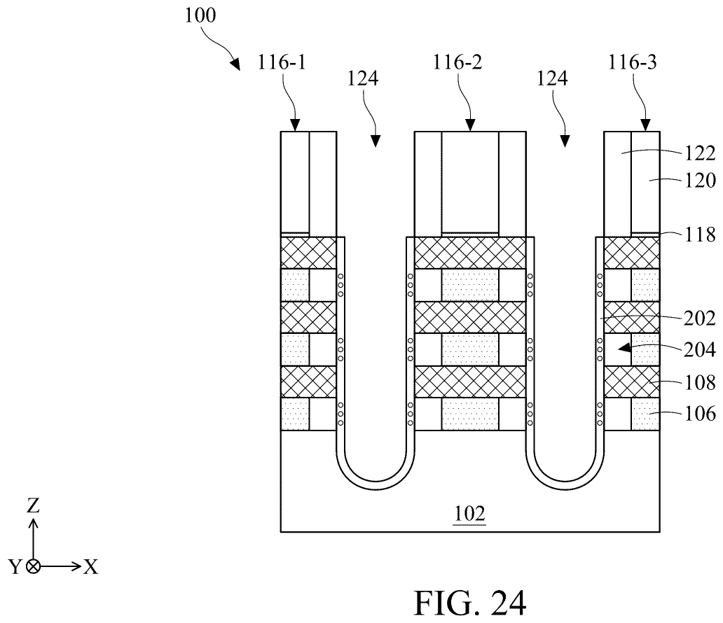

Referring to FIG. 24, the side portions of the semiconductor layers 106 are removed via a selective etching process. More specifically, although the oxide layers 202 are formed on the sidewalls of the semiconductor layers 106, the selective etching process can etch the side portions of the semiconductor layers 106 through the small holes in the oxide layers 202. The selective etching process is performed to selectively etch the side portions of the semiconductor layers 106 below the gate spacers 122 through the source/drain trenches 124, with minimal (or no) etching of semiconductor layers 108, the gate spacers 122, the substrate 102, and the oxide layers 202, such that gaps 204 are formed vertically between (the side portions of) the semiconductor layers 108 in the Z-direction as well as vertically between (the side portions of) the semiconductor layers 108 and the substrate 102 in the Z-direction, and below the gate spacers 122. The etching process is configured to laterally etch (e.g., along the X-direction) the semiconductor layers 106 below the gate spacers 122. The selective etching process is a dry etching process, a wet etching process, other suitable etching process, or combinations thereof.

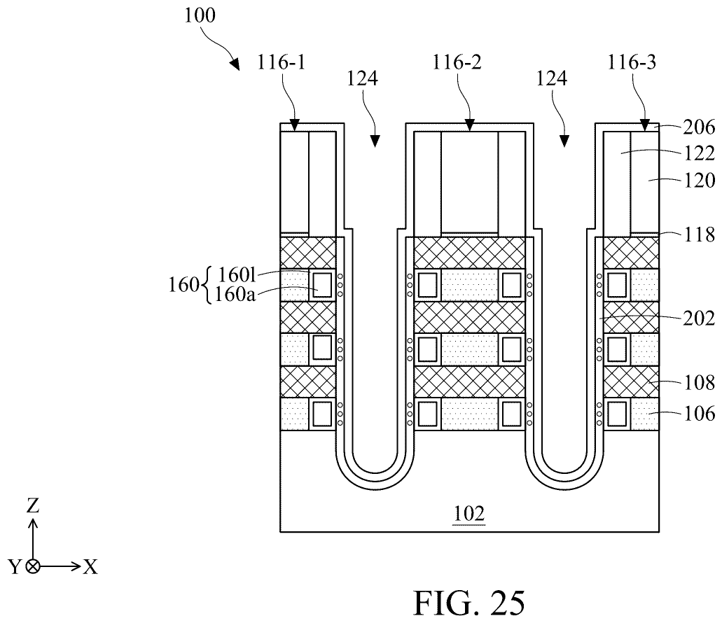

Referring to FIG. 25, a dielectric layer 206 is formed in the source/drain trenches 124 and the gaps 204 to form the inner spacers 160 discussed above. More specifically, the dielectric layer 206 is conformally formed on (the sidewalls of) the oxide layers 202, on (the sidewalls of) the gate spacers 122, over the dummy gate structures 116, and into the gaps 204. Portions of the dielectric layer 206 formed into the gaps 204 construct the liner layer 160l of the inner spacers 160. Similarly, each of the inner spacers 160 has the air gap 160a and the liner layer 160l formed of the dielectric layer 206, as shown in FIG. 25. The liner layer 160l wraps around the air gap 160a to construct the inner spacer 160. In other words, the dielectric layer 206 partially fills the gaps 154 to form the inner spacers 160 with air gaps 160a. The dielectric layer 206 is similar to the dielectric layer 156 discussed above. In some embodiments, the dielectric layer 206 (and thus the liner layer 160l of the inner spacers 160) includes silicon, oxygen, carbon, nitrogen, other suitable material, or combinations thereof (for example, silicon oxide (SiOₓ), silicon nitride (Si₃N₄), silicon carbon (SiC), silicon oxynitride (SiON), silicon oxycarbide (SiOC), silicon carbon nitride (SiCN), silicon oxycarbon nitride (SiOCN)). Other characteristics of the inner spacers 160 are as discussed above and will not be described repeatedly here. Therefore, the inner spacers 160 with the air gaps 160a are formed before the formation of the gate spacers 158 with the air gaps 158a.

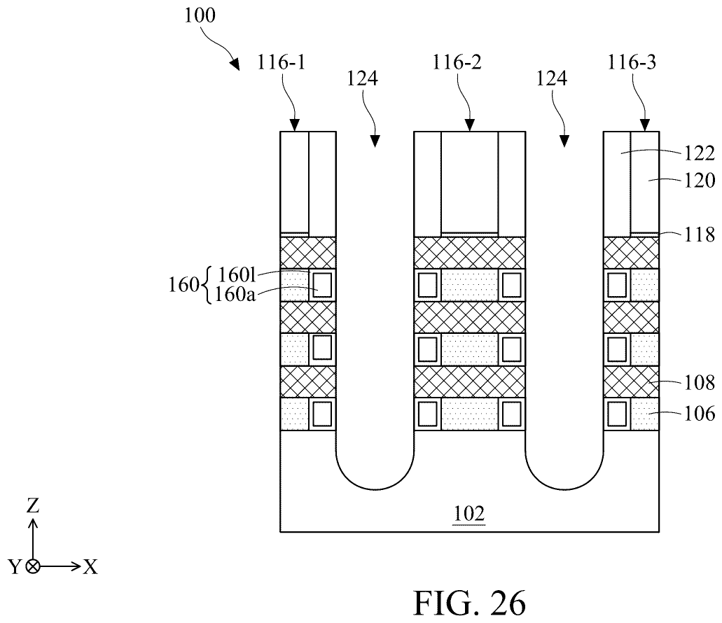

Referring to FIG. 26, the oxide layers 202 and the dielectric layer 206 formed on (the sidewalls of) the oxide layers 202, on (the sidewalls of) the gate spacers 122, and over the dummy gate structures 116 are removed and the dielectric layer 206 in the gaps 204 remain (i.e., the inner spacers 160). More specifically, a selective etching process is performed that selectively etches the dielectric layer 206 other than that in the gaps 204 and the oxide layers 202, with minimal (or no) etching of semiconductor layers 108, the gate spacers 122, the inner spacers 160, and the substrate 102, such that the dielectric layer 206 in the gaps 204 between (the side portions of) the semiconductor layers 108 in the Z-direction as well as vertically between (the side portions of) the semiconductor layers 108 and the substrate 102 in the Z-direction remain to form the inner spacers 160 with the air gaps 160a. The selective etching process is a dry etching process, a wet etching process, other suitable etching process, or combinations thereof.

Referring to FIGS. 27A and 27B, after the formation of the inner spacers 160 with the air gaps 160a, the silicon layers 130, the bottom dielectric layers 132, the source/drain features 134, the CESL 136, and the ILD layer 138 discussed are formed by the processes discussed above. Then, the interfacial layers 148 and the gate structures 142 with the gate dielectric layers 144 and the gate electrode layers 146 discussed above are formed by the processes discussed above to replace the dummy gate structures 116. Furthermore, the source/drain contacts 150 discussed above are formed over the source/drain features 134. As such, the structure of the workpiece 100 similar to the structure of the workpiece 100 shown in FIG. 16B is provided, except that the inner spacers 160 with the air gaps 160a have been formed.

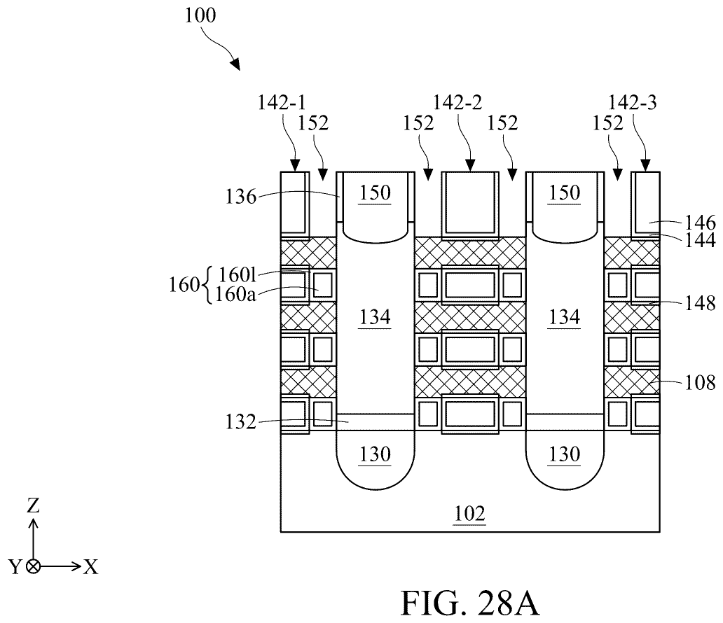

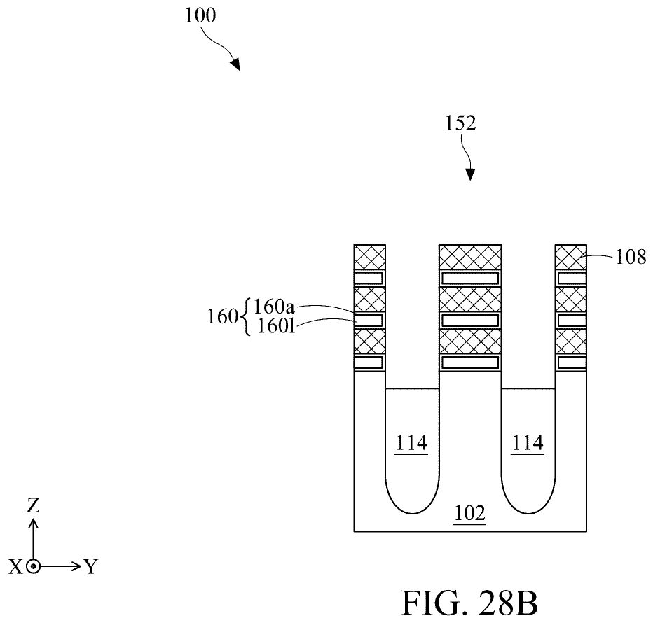

As shown in FIG. 27B, the inner spacers 160 with the air gaps 160a are in contact with the gate spacers 122 without air gaps in the Y-direction. It is noted that the air gaps 160a of the inner spacers 160 are separated from the gate spacers 122 by the liner layer 160l of the inner spacers 160. Referring to FIGS. 28A and 28B, the gate spacers 122 are removed. More specifically, an etching processes is performed to remove the gate spacers 122. The etching process is a selective etching process that selectively the gate spacers 122, with minimal (or no) etching of the semiconductor layers 108, the isolation features 114, the gate structures 142 (specifically, the gate dielectric layers 144), the inner spacers 160, the source/drain features 134, and the substrate 102, such that the trenches 152 discussed above are formed. The trenches 152 are over and exposed the isolation features 114, the inner spacers 160, and the semiconductor layers 108. As shown in FIG. 28B, the trenches 152 are separated from the air gaps 160a of the inner spacers 160 by the liner layer 160l of the inner spacers 160, in accordance with some embodiments. The selective etching process is a dry etching process, a wet etching process, other suitable etching process, or combinations thereof.

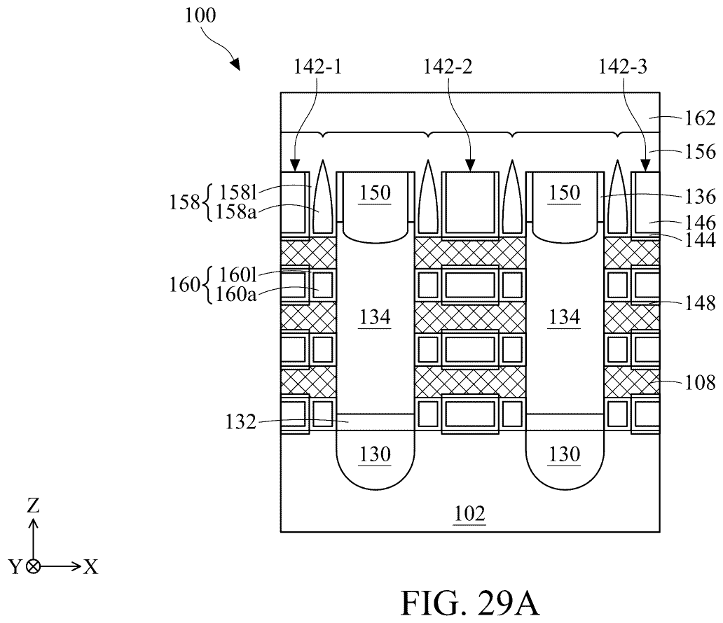

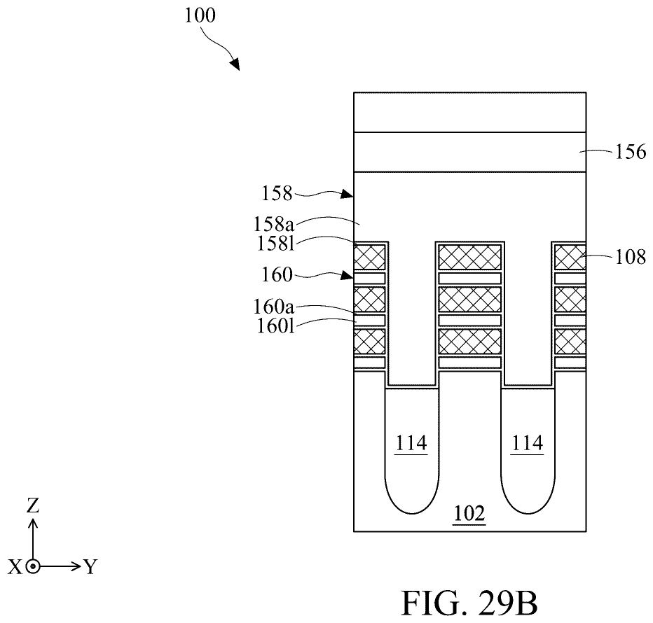

Referring to FIGS. 29A and 29B, a dielectric layer 156 is formed in the trenches 152 to form the gate spacers 158 discussed above. As shown in FIGS. 29A and 29B, the gate spacers 158 replace the gate spacers 122. In some embodiments, each of the gate spacers 158 has the air gap 158a and the liner layer 1581 formed of the dielectric layer 156, as shown in FIGS. 29A and 29B. In some aspects, the liner layer 1581 wraps around the air gap 158a to construct the gate spacer 158. In other words, the dielectric layer 156 partially fills the trenches 152 to form the gate spacers 158 with air gaps 158a.

Therefore, the gate spacers 158 are formed after the formation of the inner spacers 160. The gate spacers 158 shown in FIGS. 29A and 29B are similar to the gate spacers 158 shown in FIGS. 18A to 18C, except that the gate spacers 158 are separated from the air gaps 160a of the inner spacers 160. In some aspects, the air gaps 158a of the gate spacers 158 are separated from the inner spacers 160. In other words, the air gaps 158a of the gate spacers 158 are separated from the air gaps 160a of the inner spacers 160 by the liner layer 1581 of the gate spacers 158 and/or the liner layer 160l of the inner spacers 160, as shown in FIG. 29B. Still referring to FIGS. 29A and 29B, the ILD layer 162 discussed above is formed over the dielectric layer 156 (or the gate spacers 158).

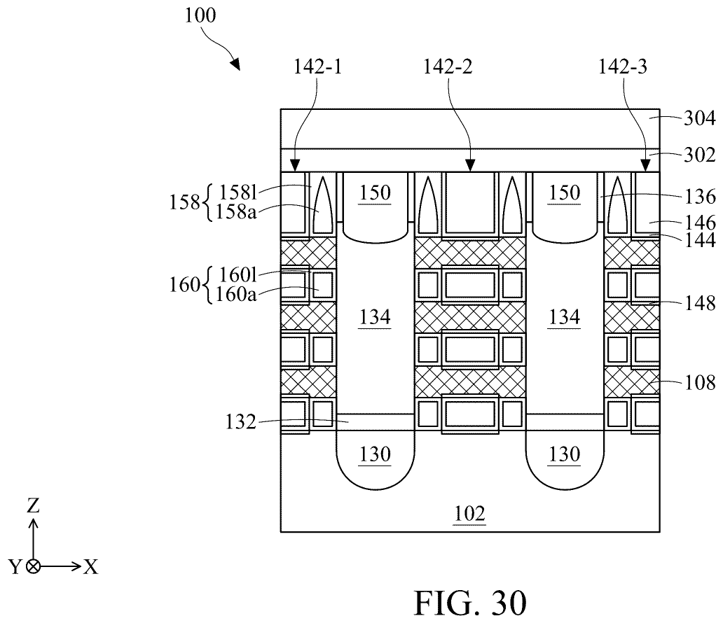

FIG. 30 is an X-Z cross-sectional view of the workpiece 100 at various fabrication stages, in accordance with some alternative embodiments of the present disclosure. Referring back to FIG. 18B, the highest points of the air gaps 158a of the gate spacers 158 are higher than top surfaces (specifically, the topmost surfaces) of the gate structures 142, as discussed above. The structure shown in FIG. 30 is similar to the structure shown in FIG. 18B, except that the highest points of the air gaps 158a of the gate spacers 158 are lower than top surfaces (specifically, the topmost surfaces) of the gate structures 142. In some embodiments, in the case that the highest points of the air gaps 158a of the gate spacers 158 are lower than top surfaces of the gate structures 142, a CMP process may be performed on the dielectric layer 156 (or the gate spacers 158) to remove a portion of the dielectric layer 156 over the gate structure, such that the top surfaces of the gate structures 142 are exposed. Therefore, as shown in FIG. 30, top surfaces of the gate spacers 158 (or the dielectric layer 156) are substantially level with the top surfaces of the gate structures 142. In some embodiments, after the CMP process, a CESL 302 is formed over the gate spacers 158 and the gate structures 142 and an ILD layer 304 is formed over the CESL 302. The CESL 302 is similar to the CESL 136 discussed above and the ILD layer 304 is similar to the ILD layer 162 discussed above.

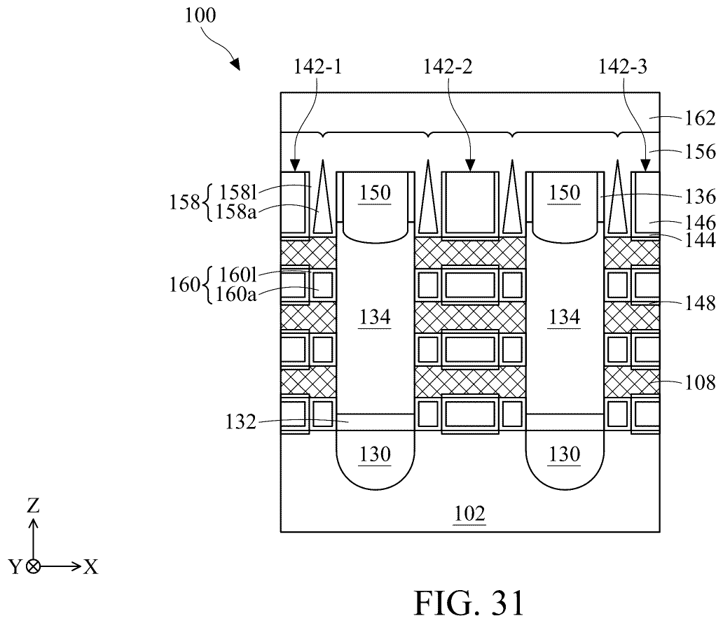

FIG. 31 is an X-Z cross-sectional view of the workpiece 100 at various fabrication stages, in accordance with some alternative embodiments of the present disclosure. Referring back to FIG. 18B, each of the air gaps 158a of the gate spacers 158 has a bullet shape in the X-Z cross-sectional view, as discussed above. The structure shown in FIG. 31 is similar to the structure shown in FIG. 18B, except that each of the air gaps 158a of the gate spacers 158 has a triangular shape in the X-Z cross-sectional view. More specifically, in some embodiments, each of the air gaps 158a of the gate spacers 158 has an isosceles triangular shape in the X-Z cross-sectional view in the X-Z cross-sectional view, as shown in FIG. 31.

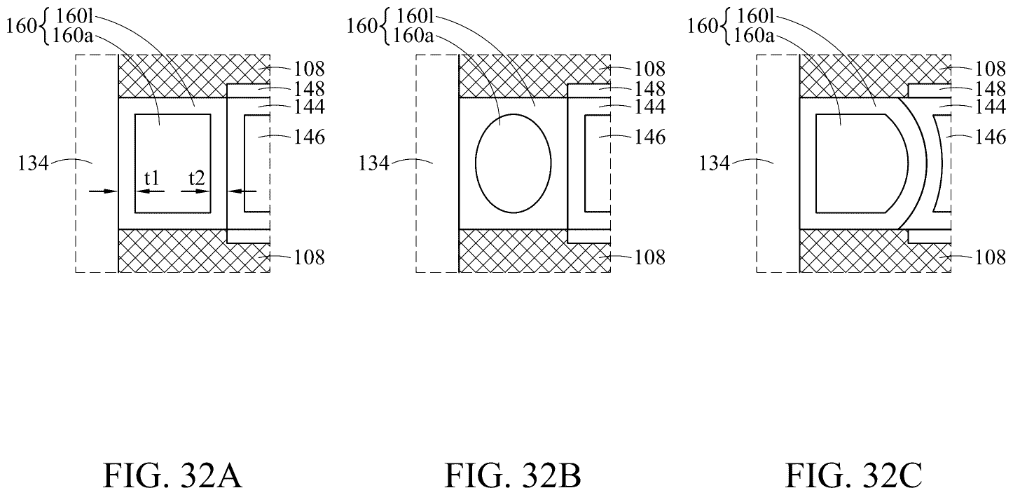

FIG. 32A is a partial enlarged cross-sectional view of the workpiece 100 at the fabrication stage in a dashed box of FIG. 20B, in accordance with some alternative embodiments of the present disclosure. As discussed above, the thickness of the liner layers 160l of the inner spacers 160 is in a range from about 0.1 nm to about 1 nm. In some embodiments, the thickness of the liner layers 160l is uniform. In other embodiments, the liner layers 160l have non-uniform thickness. More specifically, the thickness t1 of the liner layers 160l of the inner spacers 160 in contact with the source/drain feature 134 is less than the thickness of the liner layers 160l of the inner spacers 160 in contact with the gate structures 142 (specifically, the gate dielectric layers 144), as shown in FIG. 32A.

FIG. 32B is a partial enlarged cross-sectional views of the workpiece 100 at the fabrication stage in the dashed box of FIG. 20B, in accordance with some alternative embodiments of the present disclosure.

Referring back to FIG. 18B, each of the air gaps 160a of the inner spacers 160 has the rectangular shape in the X-Z cross-sectional view. In some embodiments, the air gaps 160a of the inner spacers 160 have different shapes. The inner spacer 160 shown in FIG. 32B is similar to the inner spacer 160 shown in FIG. 20B discussed above, except that the inner spacer 160 has a non-rectangular shape in the X-Z cross-sectional view. More specifically, the air gaps 160a of the inner spacers 160 have an elliptical shape in the X-Z cross-sectional view, as shown in FIG. 32B.

FIG. 32C is a partial enlarged cross-sectional views of the workpiece 100 at the fabrication stage in the dashed box of FIG. 20B, in accordance with some alternative embodiments of the present disclosure. The inner spacers 160 shown in FIG. 32C are similar to the inner spacers 160 shown in FIG. 18B discussed above, except that the inner spacers 160 have a half-ellipse-shape in the X-Z cross-sectional view. As shown in FIG. 32C, each of the air gaps 160a of the inner spacers 160 also has a half-ellipse-shape and each of the liner layers 160l of the inner spacers 160 has a hollow half-ellipse-shape wrapping around the air gaps 160a in the X-Z cross-sectional view. More specifically, the inner spacers 160 have vertical surfaces/sidewalls in contact with the source/drain features 134 and convex surfaces/sidewalls in contact with the gate structures 142. Therefore, each of the liner layers 160l also includes a vertical surfaces/sidewall in contact with the source/drain feature 134 and a convex surfaces/sidewall in contact with the gate structure 142. In some embodiments, such shape of the inner spacers 160 may also be referred to as D-shape.

The embodiments disclosed herein relate to semiconductor structures and their manufacturing methods, and more particularly to methods and semiconductor structures including gate spacers and inner spacers with air gaps. Furthermore, the present embodiments provide one or more of the following advantages. The gate spacers and inner spacers with air gaps are formed after the formation of the gate structures, such that the features can be support by the gate spacers and inner spacers without air gaps before the formation of the gate structures. Then, the gate spacers and inner spacers with air gaps formed after the formation of the gate structures can reduce the parasitic capacitance of the GAA transistor, thereby improving the performance of the GAA transistor.

Thus, one of the embodiments of the present disclosure describes a method for manufacturing a semiconductor structure that includes forming a fin over a substrate. The fin includes first semiconductor layers and second semiconductor layers alternating stacked in a Z-direction. The method further includes forming a dummy gate structure over the fin, forming first gate spacers on opposite sides of the dummy gate structure in an X-direction, forming source/drain features on opposite sides of the dummy gate structure in the X-direction, replacing the dummy gate structure and the first semiconductor layers with a gate structure, replacing the first gate spacers with second gate spacers, and forming inner spacers between the second semiconductor layers in the Z-direction. The gate structure wraps around the first semiconductor layers. Each of the second gate spacers has a first air gap. Each of the inner spacers has a second air gap.

In some embodiments, the replacement of the dummy gate structure and the first semiconductor layers with the gate structure includes removing the dummy gate structure and the first semiconductor layers to form a gate trench, forming a gate dielectric layer in the gate trench and wrapping around the second semiconductor layers, and forming a gate electrode layer in the gate trench and wrapping around the gate dielectric layer and the second semiconductor layers.

In some embodiments, the method further includes removing the gate dielectric layer on sidewalls of the gate electrode layer and forming the second gate spacers and the inner spacers in contact with the sidewalls of the gate electrode layer.

In some embodiments, the method further includes forming sacrificial inner spacers under the first gate spacers and between the second semiconductor layers in the Z-direction and replacing the sacrificial inner spacers with the inner spacers.

In some embodiments, the replacement of the first gate spacers with the second gate spacers and the replacement of the sacrificial inner spacers with the inner spacers includes performing an etching process to remove the first gate spacers to form trenches and the sacrificial inner spacers to form gaps and forming a dielectric layer in the trenches, in the gaps, and over the a gate structure to form the second gate spacers and the inner spacers.

In some embodiments, highest points of the first air gaps are higher than a top surface of the gate structure.

In some embodiments, the method further includes removing a portion of the dielectric layer over the gate structure.

In some embodiments, highest points of the first air gaps are lower than a top surface of the gate structure.

In some embodiments, the method further includes forming an oxide layer with small holes on sidewalls of the first semiconductor layers in the X-direction, removing side portions of the first semiconductor layers through the small holes of the oxide layer to form gaps, forming a dielectric layer on sidewalls of the oxide layer and in the gaps to form the inner spacers, and removing the dielectric layer on the sidewalls of the oxide layer and removing the oxide layer.

In some embodiments, the first air gaps are separated from the second air gaps.

In another of the embodiments, discussed is a method for manufacturing a semiconductor structure including forming a fin over a substrate. The fin includes first semiconductor layers and second semiconductor layers alternating stacked in a Z-direction. The method further includes forming a dummy gate structure extending in a Y-direction and over the fin, forming sacrificial gate spacers on sidewalls of the dummy gate structure in an X-direction, forming sacrificial inner spacers under the sacrificial gate spacers and between the second semiconductor layers in the Z-direction, forming source/drain features attached to the second semiconductor layers in the X-direction, replacing the dummy gate structure and the first semiconductor layers with a gate structure, removing the sacrificial gate spacers to form trenches, removing the sacrificial inner spacers to form gaps, forming gate spacers having first air gaps in the trenches, and forming inner spacers having second air gaps in the gaps. The gate structure wraps around the first semiconductor layers.

In some embodiments, the method further includes forming bottom dielectric layers over the substrate and forming the source/drain features over the bottom dielectric layers. The bottom dielectric layers are in contact with the inner spacers in the X-direction.

In some embodiments, the first air gaps are connected to the second air gaps.

In some embodiments, the first air gaps have a bullet shape in an X-Z cross-sectional view.

In some embodiments, the second air gaps of the inner spacers have a rectangular shape in an X-Z cross-sectional view.

In some embodiments, the second air gaps of the inner spacers have an elliptical shape in an X-Z cross-sectional view.

In yet another of the embodiments, discussed is a semiconductor structure including a substrate, nanostructures, a gate structure, gate spacers, inner spacers, and source/drain features. The nanostructures are over the substrate and spaced apart from each other in a Z-direction. The gate structure extends in a Y-direction and wraps around the nanostructures. The gate spacers are on opposite sides of the gate structure in an X-direction. Each of the gate spacers has a first air gap. The inner spacers are between the nanostructures in the Z-direction. Each of the inner spacers has a second air gap. The source/drain features are on opposite sides of the gate structure in the X-direction and attached to the nanostructures in the X-direction.

In some embodiments, each of the inner spacers has a convex surface in contact with the gate structure.

In some embodiments, the first air gaps of the gate spacers have a triangular shape.

In some embodiments, each of the inner spacers has a liner layer wrapping around the second air gap, wherein a thickness of the liner layer in contact with the source/drain feature is less than a thickness of the liner layer in contact with the gate structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for manufacturing a semiconductor structure, comprising:
forming a fin over a substrate, wherein the fin comprises first semiconductor layers and second semiconductor layers alternating stacked in a first direction;
forming a dummy gate structure over the fin;
forming first gate spacers on opposite sides of the dummy gate structure in a second direction;
forming source/drain features on opposite sides of the dummy gate structure in the second direction;
replacing the dummy gate structure and the first semiconductor layers with a gate structure, wherein the gate structure wraps around the first semiconductor layers;
replacing the first gate spacers with second gate spacers, wherein each of the second gate spacers has a first air gap; and
forming inner spacers between the second semiconductor layers in the first direction, wherein each of the inner spacers has a second air gap.

2. The method of claim 1, wherein the replacement of the dummy gate structure and the first semiconductor layers with the gate structure comprises:
removing the dummy gate structure and the first semiconductor layers to form a gate trench;
forming a gate dielectric layer in the gate trench and wrapping around the second semiconductor layers; and
forming a gate electrode layer in the gate trench and wrapping around the gate dielectric layer and the second semiconductor layers.

3. The method of claim 2, further comprising:
removing the gate dielectric layer on sidewalls of the gate electrode layer; and
forming the second gate spacers and the inner spacers in contact with the sidewalls of the gate electrode layer.

4. The method of claim 1, further comprising:
forming sacrificial inner spacers under the first gate spacers and between the second semiconductor layers in the first direction; and
replacing the sacrificial inner spacers with the inner spacers.

5. The method of claim 4, wherein the replacement of the first gate spacers with the second gate spacers and the replacement of the sacrificial inner spacers with the inner spacers comprises:
performing an etching process to remove the first gate spacers to form trenches and the sacrificial inner spacers to form gaps; and
forming a dielectric layer in the trenches, in the gaps, and over the a gate structure to form the second gate spacers and the inner spacers.

6. The method of claim 5, wherein highest points of the first air gaps are higher than a top surface of the gate structure.

7. The method of claim 5, further comprising:
removing a portion of the dielectric layer over the gate structure.

8. The method of claim 7, wherein highest points of the first air gaps are lower than a top surface of the gate structure.

9. The method of claim 1, wherein the formation of the inner spacers comprises:
forming an oxide layer with small holes on sidewalls of the first semiconductor layers in the second direction;
removing side portions of the first semiconductor layers through the small holes of the oxide layer to form gaps;
forming a dielectric layer on sidewalls of the oxide layer and in the gaps to form the inner spacers; and
removing the dielectric layer on the sidewalls of the oxide layer and removing the oxide layer.

10. The method of claim 9, wherein the first air gaps are separated from the second air gaps.

11. A method for manufacturing a semiconductor structure, comprising:
forming a fin over a substrate, wherein the fin comprises first semiconductor layers and second semiconductor layers alternating stacked in a first direction;
forming a dummy gate structure extending in a second direction and over the fin;
forming sacrificial gate spacers on sidewalls of the dummy gate structure in a third direction;
forming sacrificial inner spacers under the sacrificial gate spacers and between the second semiconductor layers in the first direction;
forming source/drain features attached to the second semiconductor layers in the third direction;
replacing the dummy gate structure and the first semiconductor layers with a gate structure, wherein the gate structure wraps around the first semiconductor layers;
removing the sacrificial gate spacers to form trenches;
removing the sacrificial inner spacers to form gaps;
forming gate spacers having first air gaps in the trenches; and
forming inner spacers having second air gaps in the gaps.

12. The method of claim 11, further comprising:
forming bottom dielectric layers over the substrate; and
forming the source/drain features over the bottom dielectric layers,
wherein the bottom dielectric layers are in contact with the inner spacers in the third direction.

13. The method of claim 11, wherein the first air gaps are connected to the second air gaps.

14. The method of claim 11, wherein the first air gaps have a bullet shape in an X-Z cross-sectional view.

15. The method of claim 11, wherein the second air gaps of the inner spacers have a rectangular shape in a cross-sectional view.

16. The method of claim 11, wherein the second air gaps of the inner spacers have an elliptical shape in a cross-sectional view.

17. A semiconductor structure, comprising:
a substrate;
nanostructures over the substrate and spaced apart from each other in a first direction;
a gate structure extending in a second direction and wrapping around the nanostructures;
gate spacers on opposite sides of the gate structure in a third direction, wherein each of the gate spacers has a first air gap;
inner spacers between the nanostructures in the first direction, wherein each of the inner spacers has a second air gap; and
source/drain features on opposite sides of the gate structure in the third direction and attached to the nanostructures in the third direction.

18. The semiconductor structure of claim 17, wherein each of the inner spacers has a convex surface in contact with the gate structure.

19. The semiconductor structure of claim 17, wherein the first air gaps of the gate spacers have a triangular shape.

20. The semiconductor structure of claim 17, wherein each of the inner spacers has a liner layer wrapping around the second air gap, wherein a thickness of the liner layer in contact with the source/drain feature is less than a thickness of the liner layer in contact with the gate structure.
